(19) United States
(12) Patent Application Publication
(10) Pub. No.: US 2026/0206376 A1
(43) Pub. Date: Jul. 16, 2026

(54) WHITE LED WITH AT LEAST P1F3 LIGHT QUALITY

(71) Applicant: SIGNIFY HOLDING B.V., EINDHOVEN (NL)

(72) Inventors: MARTINUS PETRUS JOSEPH PEETERS, WEERT (NL); RENÉ THEODORUS WEGH, VELDHOVEN (NL); GRIGORY ALEXANDROVICH ONUSHKIN, EINDHOVEN (NL)

(21) Appl. No.: 19/131,247

(22) PCT Filed: Nov. 20, 2023
(86) PCT No.: PCT/EP2023/082370

§ 371 Date: May 20, 2025

(30) Foreign Application Priority Data
Nov. 22, 2022 (EP) 22208763.7

(51) Int. Cl. H10H 20/851; C09K 11/61; C09K 11/77

(52) U.S. Cl. CPC H10H 20/8513; C09K 11/61; C09K 11/77

(57) ABSTRACT

The invention provides a light generating system (1000) comprising a light generating device (100) and two or more luminescent materials (200), wherein: (A) the light generating device (100) is configured to generate device light (101) having a peak wavelength selected from the wavelength range of 440-465 nm; wherein the light generating device (100) comprises a solid state light source; (B) the two or more luminescent materials comprise (i) a first luminescent material (210) configured to convert at least part of the device light (101) into first luminescent material light (211) having spectral power within the green-yellow wavelength range, a full width half maximum of at least 50 nm, and a color point u′_{yellow}, v′_{yellow}; (ii) optionally a second luminescent material (220) configured to convert at least part of the device light (101) into second luminescent material light (221) having spectral power within the orange-red wavelength range, a full width half maximum of at least 50 nm, and a color point u′_{red}, v′_{red}; and (iii) a third luminescent material (230) configured to convert at least part of the device light (101) into third luminescent material light (231) within the orange-red wavelength range, wherein the third luminescent material (230) comprises M′ₓM₂₋₂ₓAX₆ doped with tetravalent manganese, wherein M′ comprises an alkaline earth cation, wherein M comprises a cation, and x is in the range of 0-1, wherein A comprises a tetravalent cation, wherein X comprises a monovalent anion, at least comprising fluorine; and (C) the light generating system (1000) is configured to generate system light (1001) comprising (i) at least part of the first device light (101), (ii) at least part of the first luminescent material light (211), and (iii) at least part of the third luminescent material light (231); wherein the system (1000) is configured such that the system light (1001) is white light having a correlated color temperature (CCT) selected from the range of 1800-6500 K, an R_{f} value of at least 85, a R_{f,h1} value of at least 85, an R_{g} value of at least 95, and an R_{cs,h1} value of at least −1%, wherein R_{f}, R_{f,h1}, R_{g}, and R_{cs,h1} are defined according to TM-30 (2020) standard ANSI/IES TM-30-20: IES Method for Evaluating Light Source Color Rendition.

### FIELD OF THE INVENTION

The invention relates to a light generating system as well as to a lighting device comprising such light generating system.

### BACKGROUND OF THE INVENTION

White-light emitting lighting devices are known in the art. US2015287890, for instance, describes a white-light emitting lighting device comprising one or more light emitting light sources (preferably solid state semiconductor light emitting diodes) that emit off-white light during operation, wherein the off-white light includes a spectral output including at least one spectral component in a first spectral region from about 360 nm to about 475 nm, at least one spectral component in a second spectral region from about 475 nm to about 575 nm, and at least one deficiency in at least one other spectral region, and an optical component that is positioned to receive at least a portion of the off-white light generated by the one or more light sources, the optical component comprising an optical material for converting at least a portion of the off-white light to one or more predetermined wavelengths, at least one of which has a wavelength in at least one deficient spectral region, such that light emitted by the lighting device comprises white light, wherein the optical material comprises quantum confined semiconductor nanoparticles.

### SUMMARY OF THE INVENTION

There is a desire to provide lighting devices and light generating systems that comply with desirable lighting quality standards. Further, there is a desire to comply with such standards in the most efficient way. Current lighting devices and/or light generating systems may not comply with these standards or may comply with these standards with a less efficient solution. Hence, it is an aspect of the invention to provide an alternative light generating system (and/or lighting device), which preferably further at least partly obviates one or more of above-described drawbacks. The present invention may have as object to overcome or ameliorate at least one of the disadvantages of the prior art, or to provide a useful alternative. It appears not obvious to meet e.g. a priority level 1, and fidelity level 3, herein also indicated as P1F3, such as described in TM-30 (2020) standard [ANSI/IES TM-30-20: IES Method for Evaluating Light Source Color Rendition https://store.ies.org/product/tm-30-20-ies-method-for-evaluating-light-source-color-rendition/(see table E-2). A number of simulations were executed, whereby it appeared that essentially only specific conditions may allow meeting e.g. the P1F3 and/or P2F3 (priority level 2 and fidelity level 3) requirements at reasonable or high energy efficiency.

According to a first aspect, the invention provides a light generating system (“system”) comprising a light generating device and two or more luminescent materials. In embodiments, the light generating device may be configured to generate device light having a peak wavelength (PWL) selected from the wavelength range of 440-465 nm. Especially, the light generating device may comprise a solid state light source. Further, especially the two or more luminescent materials may comprise a first luminescent material configured to convert at least part of the device light into first luminescent material light, especially having spectral power within the green-yellow wavelength range. In embodiments, the first luminescent material light may have a full width half maximum of at least 50 nm. Further, the first luminescent material light may have a color point u′_{yellow}, v′_{yellow}. Optionally, the two or more luminescent materials may comprise a second luminescent material configured to convert at least part of the device light into second luminescent material light, especially having a spectral power within the orange-red wavelength range. In embodiments, the second luminescent material light may have a full width half maximum of at least 50 nm, and a color point u′_{red}, v′_{red}. Yet further, the two or more luminescent materials may comprise in embodiments a third luminescent material configured to convert at least part of the device light into third luminescent material light within the orange-red wavelength range. In specific embodiments, the third luminescent material may comprise M′ₓM₂₋₂ₓAX₆ doped with tetravalent manganese, wherein M′ comprises an alkaline earth cation, wherein M comprises a cation, and x is in the range of 0-1, wherein A comprises a tetravalent cation, wherein X comprises a monovalent anion, at least comprising fluorine. Further, especially, the light generating system is configured to generate system light. In embodiments, the (spectral power distribution of the) system light may comprise (i) at least part of the device light, (ii) at least part of the first luminescent material light, and (iii) at least part of the third luminescent material light. In embodiments, the system may be configured such that the system light is white light having a correlated color temperature (CCT) selected from the range of 1800-6500 K. Further, in embodiments the system may be configured such that the system light may have one or more of (i) an R_{f} value of at least 85, (ii) an R_{f,h1} value of at least 85, (iii) an R_{g} value of at least 95, and (iv) an R_{cs,h1} value of at least −1%. Especially, R_{f}, R_{f,h1}, R_{g}, and R_{cs,h1} are defined according to TM-30 (2020) standard ANSI/IES TM-30-20: IES Method for Evaluating Light Source Color Rendition. Further, in embodiments a contribution to a spectral power distribution of the system light in the wavelength range of 380-780 nm by the third luminescent material light may be defined as a fraction G. In embodiments, the following may apply: (a) when the system light (also) comprises the second luminescent material light, the fraction G may be selected from the range of 0.95*G′-1.05*G′, wherein G′ complies with the following formula: G′=1.4421−2.904125*10⁻⁸*PWL−10.08921*u′_{Yellow}−0.5457286*u′_{Red}−1.074782*10⁻⁴*CCT+21.623*[u′_{Yellow}]²−1.639*[u′_{Red}]²+4.921703*10⁻⁹*[CCT]²+2.316461*10⁻⁷*[PWL*u′_{Red}]+7.268292*[u′_{Yellow}*u′_{Red}]+9.309924*10⁻⁵*[u′_{Red}*CCT]; and wherein the fraction G may in specific embodiments be at least 0.05 and at maximum 0.2. In (other) embodiments, the following may apply: (b) when the system light does not comprise the second luminescent material light, the following may apply: u′_{Yellow}≥0.95*(0.2546−0.000016*CCT), and the fraction G may be at least 0.05 and at maximum 0.2. Therefore, the invention provides amongst others in embodiments a light generating system comprising a light generating device and two or more luminescent materials, wherein: (A) the light generating device is configured to generate device light having a peak wavelength selected from the wavelength range of 440-465 nm; wherein the light generating device comprises a solid state light source; (B) the two or more luminescent materials comprise (i) a first luminescent material configured to convert at least part of the device light into first luminescent material light having spectral power within the green-yellow wavelength range (especially within the range of 490-590 nm), a full width half maximum of at least 50 nm, and a color point u′_{yellow}, v′_{yellow}; (ii) optionally a second luminescent material configured to convert at least part of the device light into second luminescent material light having spectral power within the orange-red wavelength range (especially within the range of 590-680 nm), a full width half maximum of at least 50 nm, and a color point u′_{red}, v′_{red}; and (iii) a third luminescent material configured to convert at least part of the device light into third luminescent material light within the orange-red wavelength range (especially within the range of 590-680 nm), wherein the third luminescent material comprises M′ₓM₂₋₂ₓAX₆ doped with tetravalent manganese, wherein M′ comprises an alkaline earth cation, wherein M comprises a cation, and x is in the range of 0-1, wherein A comprises a tetravalent cation, wherein X comprises a monovalent anion, at least comprising fluorine; (C) the light generating system is configured to generate system light comprising (i) at least part of the device light, (ii) at least part of the first luminescent material light, and (iii) at least part of the third luminescent material light; wherein the system is configured such that the system light is white light having a correlated color temperature (CCT) selected from the range of 1800-6500 K, an R_{f} value of at least 85, an R_{f,h1} value of at least 85, an R_{g} value of at least 95, and an R_{cs,h1} value of at least −1%, wherein R_{f}, R_{f,h1}, R_{g}, and R_{cs,h1} are defined according to TM-30 (2020) standard ANSI/IES TM-30-20: IES Method for Evaluating Light Source Color Rendition, wherein a contribution to a spectral power distribution of the system light in the wavelength range of 380-780 nm by the third luminescent material light is defined as a fraction G, and wherein the following applies: (a) when the system light [also] comprises the second luminescent material light, the fraction G is selected from the range of 0.95*G′-1.05*G′, wherein G′ complies with the following formula: G′=1.4421−2.904125*10⁻⁸*PWL−10.08921*u′_{Yellow}−0.5457286*u′_{Red}−1.074782*10⁻⁴*CCT+21.623*[u′_{Yellow}]²−1.639*[u′_{Red}]²+4.921703*10⁻⁹*[CCT]²+2.316461*10⁻⁷*[PWL*u′_{Red}]+7.268292*[u′_{Yellow}*u′_{Red}]+9.309924*10⁻⁵*[u′_{Red}*CCT] and wherein the fraction G is at least 0.05 and at maximum 0.2; or (b) when the system light does not comprise the second luminescent material light, the following applies: u′_{Yellow}≥0.95*(0.2546−0.000016*CCT), and the fraction G is at least 0.05 and at maximum 0.2.

With such light generating system, in a relatively efficient way high quality light can be provided. Compared to known solutions, the present invention seems to provide the highest lumen efficiencies, also in a relatively easy way. Further, such high quality light can be provided with a minimum of components, and without the need for a complex control system. Yet, the high quality light may be provided over a relatively large correlated color temperature range. Therefore, the current solution may yield essentially the most efficient solution for white LEDs compared to known solutions.

Herein, in these formulas, PWL refers to the value of the peak wavelength (in nm) of the device light of the light generating device, and CCT refers to the value of the correlated color temperature (in K) of the (desired) system light. Hence, in these equations, a value of x nm for PWL will be introduced as value x (without the nanometer unit); likewise a value of y K for CCT will be introduced as value y (without the Kelvin unit).

As indicated above, the light generating system may comprise (i) one or more light generating devices and (ii) two or more luminescent materials. It appears that to obtain a large color gamut and a relatively efficient light generating system, the use of the proposed light generating system, wherein one or more light generating devices and (ii) two or more luminescent materials, are comprised, may have certain advantages over using only primaries (like RGB LEDs; though such solution may also have (other) advantages). The presently proposed solution, however, appears to allow generation of white light in a relatively efficient way, with the white light having a relatively high color gamut and/or improved whiteness perception.

Here below, first some aspects in relation to light generating devices and luminescent materials are described, followed by some more (specific) embodiments.

A light generating device may especially be configured to generate device light. Especially, the light generating device may comprise a light source. The light source may especially configured to generate light source light. In embodiments, the device light may essentially consist of the light source light. In other embodiments, the device light May essentially consist of converted light source light. In yet other embodiments, the device light may comprise (unconverted) light source light and converted light source light. Light source light may be converted with a luminescent material into luminescent material light and/or with an upconverter into upconverted light (see also below). The term “light generating device” may also refer to a plurality of light generating devices which may provide device light having essentially the same spectral power distributions. In specific embodiments, the term “light generating device” may also refer to a plurality of light generating devices which may provide device light having different spectral power distributions.

The term “light source” may in principle relate to any light source known in the art. It may be a conventional (tungsten) light bulb, a low pressure mercury lamp, a high pressure mercury lamp, a fluorescent lamp, an LED (light emissive diode). In a specific embodiment, the light source comprises a solid state LED light source (such as an LED or laser diode (or “diode laser”)). The term “light source” may also relate to a plurality of light sources, such as 2-2000 (solid state) LED light sources. Hence, the term LED may also refer to a plurality of LEDs. Further, the term “light source” may in embodiments also refer to a so-called chip-on-board (COB) light source. The term “COB” especially refers to LED chips in the form of a semiconductor chip that is neither encased nor connected but directly mounted onto a substrate, such as a PCB. Hence, a plurality of light emitting semiconductor light source may be configured on the same substrate. In embodiments, a COB is a multi LED chip configured together as a single lighting module.

The term “light source” may also refer to a chip scaled package (CSP). A CSP may comprise a single solid state die with provided thereon a luminescent material comprising layer. The term “light source” may also refer to a midpower package. A midpower package may comprise one or more solid state die(s). The die(s) may be covered by a luminescent material comprising layer. The die dimensions may be equal to or smaller than 2 mm, such as in the range of e.g. 0.2-2 mm. Hence, in embodiments the light source comprises a solid state light source. Further, in specific embodiments, the light source comprises a chip scale packaged LED. Herein, the term “light source” may also especially refer to a small solid state light source, such as having a mini size or micro size. For instance, the light sources may comprise one or more of mini LEDs and micro LEDs. Especially, in embodiment the light sources comprise micro LEDs or “microLEDs” or “μLEDs”. Herein, the term mini size or mini LED especially indicates to solid state light sources having dimensions, such as die dimension, especially length and width, selected from the range of 100 μm-1 mm. Herein, the term u size or micro LED especially indicates to solid state light sources having dimensions, such as die dimension, especially length and width, selected from the range of 100 μm and smaller.

The light source may have a light escape surface. Referring to conventional light sources such as light bulbs or fluorescent lamps, it may be an outer surface of a glass or a quartz envelope. For LED's it may for instance be the LED die, or when a resin is applied to the LED die, the outer surface of the resin. In principle, it may also be the terminal end of a fiber. The term escape surface especially relates to that part of the light source, where the light actually leaves or escapes from the light source. The light source is configured to provide a beam of light. This beam of light (thus) escapes from the light exit surface of the light source.

Likewise, a light generating device may comprise a light escape surface, such as an end window. Further, likewise a light generating system may comprise a light escape surface, such as an end window.

The term “light source” may refer to a semiconductor light-emitting device, such as a light emitting diode (LEDs), a resonant cavity light emitting diode (RCLED), a vertical cavity laser diode (VCSELs), an edge emitting laser, etc., The term “light source” may also refer to an organic light-emitting diode (OLED), such as a passive-matrix (PMOLED) or an active-matrix (AMOLED). In a specific embodiment, the light source comprises a solid-state light source (such as an LED or laser diode). In an embodiment, the light source comprises an LED (light emitting diode). The terms “light source” or “solid state light source” may also refer to a superluminescent diode (SLED).

The term LED may also refer to a plurality of LEDs.

The term “light source” may also relate to a plurality of (essentially identical (or different)) light sources, such as 2-2000 solid state light sources. In embodiments, the light source may comprise one or more micro-optical elements (array of micro lenses) downstream of a single solid-state light source, such as an LED, or downstream of a plurality of solid-state light sources (i.e. e.g. shared by multiple LEDs). In embodiments, the light source may comprise an LED with on-chip optics. In embodiments, the light source comprises pixelated single LEDs (with or without optics) (offering in embodiments on-chip beam steering).

In embodiments, the light source may be configured to provide primary radiation, which is used as such, such as e.g. a blue light source, like a blue LED, or a green light source, such as a green LED, and a red light source, such as a red LED. Such LEDs, which may not comprise a luminescent material (“phosphor”) may be indicated as direct color LEDs.

In other embodiments, however, the light source may be configured to provide primary radiation and part of the primary radiation is converted into secondary radiation. Secondary radiation may be based on conversion by a luminescent material. The secondary radiation may therefore also be indicated as luminescent material radiation. The luminescent material may in embodiments be comprised by the light source, such as an LED with a luminescent material layer or dome comprising luminescent material. Such LEDs may be indicated as phosphor converted LEDs or PC LEDs (phosphor converted LEDs). In other embodiments, the luminescent material may be configured at some distance (“remote”) from the light source, such as an LED with a luminescent material layer not in physical contact with a die of the LED. Hence, in specific embodiments the light source may be a light source that during operation emits at least light at wavelength selected from the range of 380-470 nm. However, other wavelengths may also be possible. This light may partially be converted by the luminescent material.

In embodiments, the light generating device may comprise a luminescent material. In embodiments, the light generating device may comprise a PC LED. In other embodiments, the light generating device may comprise a direct LED (i.e. no phosphor). In embodiments, the light generating device may comprise a laser device, like a laser diode. In embodiments, the light generating device may comprise a superluminescent diode. Hence, in specific embodiments, the light source may be selected from the group of laser diodes and superluminescent diodes. In other embodiments, the light source may comprise an LED.

The light source may especially be configured to generate light source light having an optical axis (O), (a beam shape,) and a spectral power distribution. The light source light may in embodiments comprise one or more bands, having band widths as known for lasers.

The term “light source” may (thus) refer to a light generating element as such, like e.g. a solid state light source, or e.g. to a package of the light generating element, such as a solid state light source, and one or more of a luminescent material comprising element and (other) optics, like a lens, a collimator. A light converter element (“converter element” or “converter”) may comprise a luminescent material comprising element. For instance, a solid state light source as such, like a blue LED, is a light source. A combination of a solid state light source (as light generating element) and a light converter element, such as a blue LED and a light converter element, optically coupled to the solid state light source, may also be a light source (but may also be indicated as light generating device). Hence, a white LED is a light source (but may e.g. also be indicated as (white) light generating device).

The term “light source” herein may also refer to a light source comprising a solid state light source, such as an LED or a laser diode or a superluminescent diode.

The term “light source” may (thus) in embodiments also refer to a light source that is (also) based on conversion of light, such as a light source in combination with a luminescent converter material. Hence, the term “light source” may also refer to a combination of an LED with a luminescent material configured to convert at least part of the LED radiation, or to a combination of a (diode) laser with a luminescent material configured to convert at least part of the (diode) laser radiation.

In embodiments, the term “light source” may also refer to a combination of a light source, like an LED, and an optical filter, which may change the spectral power distribution of the light generated by the light source. Especially, the term “light generating device” may be used to address a light source and further (optical components), like an optical filter and/or a beam shaping element, etc.

The phrases “different light sources” or “a plurality of different light sources”, and similar phrases, may in embodiments refer to a plurality of solid-state light sources selected from at least two different bins. Likewise, the phrases “identical light sources” or “a plurality of same light sources”, and similar phrases, may in embodiments refer to a plurality of solid-state light sources selected from the same bin.

The term “solid state light source”, or “solid state material light source”, and similar terms, may especially refer to semiconductor light sources, such as a light emitting diode (LED), a diode laser, or a superluminescent diode.

Hence, each of the one or more light generating devices may comprise one or more solid state light sources, such as LEDs, diode lasers, and superluminescent diodes.

Especially, the light generating device is configured to generate device light having a peak wavelength (PWL) selected from the wavelength range of 440-465 nm. In embodiments wherein two or more light generating devices are applied, two or more light generating devices may have a peak wavelength in the wavelength range of 440-465 nm. The peak wavelengths may essentially the same, or the two or more peak wavelengths may mutually differ. In specific embodiments, the device light may have a peak wavelength (PWL) selected from the wavelength range of 445-460 nm. The most efficient solutions and/or best spectral properties were obtained with these values.

Especially, the light generating system comprises two or more luminescent materials. The two or more luminescent materials are configured downstream of the light generating device.

Especially, in embodiments the system may comprise the one or more a light generating devices and a luminescent element, wherein the luminescent element comprises the first luminescent material, (optionally) the second luminescent material, and the third luminescent material, wherein the luminescent element is configured downstream of the one or more a light generating devices. In specific embodiments, the luminescent element may be configured in contact with the one or more a light generating devices. As will be clear to a person skilled in the art, phrases like “the first luminescent material, optionally the second luminescent material, and the third luminescent material”, may also be worded as “the first luminescent material and the third luminescent material and optionally the second luminescent material”.

The terms “upstream” and “downstream” relate to an arrangement of items or features relative to the propagation of the light from a light generating means (here the especially the light source), wherein relative to a first position within a beam of light from the light generating means, a second position in the beam of light closer to the light generating means is “upstream”, and a third position within the beam of light further away from the light generating means is “downstream”.

In embodiments, the two or more luminescent materials may be comprised in a layer, a multi-layer, or a body. The body may be a polymeric body (including a silicone body) or a ceramic body. Hence, the light generating system may comprise a luminescent element, such as a luminescent body, comprising the two or more luminescent materials. The luminescent element may comprise a multilayer. Hence, the two or more luminescent materials may be available homogenously mixed (and comprised in a single layer or body) or may be comprised in different layers. The luminescent element, such as the luminescent body or luminescent (multi) layer, may be in contact with the light generating device, or may be configured remote thereof. Especially, the luminescent body or luminescent layer may be in contact with the light generating device, such as in contact with a LED die.

In specific embodiments the light generating system may e.g. comprise a chip-on-board (COB) (see also above), a LED filament, or a LED package, comprising the light generating device and the two or more luminescent materials.

The term “luminescent material” especially refers to a material that can convert first radiation, especially one or more of UV radiation and blue radiation, into second radiation. In general, the first radiation and second radiation have different spectral power distributions. Hence, instead of the term “luminescent material”, also the terms “luminescent converter” or “converter” may be applied. In general, the second radiation has a spectral power distribution at larger wavelengths than the first radiation, which is the case in the so-called down-conversion. In specific embodiments, however the second radiation has a spectral power distribution with intensity at smaller wavelengths than the first radiation, which is the case in the so-called up-conversion.

In embodiments, the “luminescent material” may especially refer to a material that can convert radiation into e.g. visible and/or infrared light. For instance, in embodiments the luminescent material may be able to convert one or more of UV radiation and blue radiation, into visible light. The luminescent material may in specific embodiments also convert radiation into infrared radiation (IR). Hence, upon excitation with radiation, the luminescent material emits radiation. In general, the luminescent material will be a down converter, i.e. radiation of a smaller wavelength is converted into radiation with a larger wavelength (λₑₓ<λₑₘ), though in specific embodiments the luminescent material may comprise up-converter luminescent material, i.e. radiation of a larger wavelength is converted into radiation with a smaller wavelength (λₑₓ>λₑₘ).

In embodiments, the term “luminescence” may refer to phosphorescence. In embodiments, the term “luminescence” may also refer to fluorescence. Instead of the term “luminescence”, also the term “emission” may be applied. Hence, the terms “first radiation” and “second radiation” may refer to excitation radiation and emission (radiation), respectively. Likewise, the term “luminescent material” may in embodiments refer to phosphorescence and/or fluorescence.

The term “luminescent material” may also refer to a plurality of different luminescent materials. Examples of possible luminescent materials are indicated below. Hence, the term “luminescent material” may in specific embodiments also refer to a luminescent material composition. Instead of the term “luminescent material” also the term “phosphor” may be applied. These terms are known to the person skilled in the art.

In embodiments, luminescent materials are selected from garnets and nitrides, especially doped with trivalent cerium or divalent europium, respectively. The term “nitride” may also refer to oxynitride or nitridosilicate, etc. Alternatively or additionally, the luminescent material(s) may be selected from silicates, especially doped with divalent europium.

In specific embodiments the luminescent material comprises a luminescent material of the type A₃B₅O₁₂:Ce³⁺, wherein A in embodiments comprises one or more of Y, La, Gd, Tb and Lu, especially (at least) one or more of Y, Gd, Tb and Lu, and wherein B in embodiments comprises one or more of Al, Ga, In and Sc. Especially, A may comprise one or more of Y, Gd and Lu, such as especially one or more of Y and Lu. Especially, B may comprise one or more of Al and Ga, more especially at least Al, such as essentially entirely Al. Hence, especially suitable luminescent materials are cerium comprising garnet materials. Embodiments of garnets especially include A₃B₅O₁₂ garnets, wherein A comprises at least yttrium or lutetium and wherein B comprises at least aluminum. Such garnets may be doped with cerium (Ce), with praseodymium (Pr) or a combination of cerium and praseodymium; especially however with Ce. Especially, B may comprise aluminum (Al); however, in addition to aluminum, B may also partly comprise gallium (Ga) and/or scandium (Sc) and/or indium (In), especially up to about 20% of B, more especially up to about 10% of B (i.e. the B ions essentially consist of 90 or more mole % of Al and 10 or less mole % of one or more of Ga, Sc and In); B may especially comprise up to about 10% gallium. In another variant, B and O may at least partly be replaced by Si and N. The element A may especially be selected from the group consisting of yttrium (Y), gadolinium (Gd), terbium (Tb) and lutetium (Lu). Further, Gd and/or Tb are especially only present up to an amount of about 20% of A. In a specific embodiment, the garnet luminescent material comprises (Y₁₋ₓLuₓ)₃B₅O₁₂:Ce, wherein x is equal to or larger than 0 and equal to or smaller than 1. The term “:Ce”, indicates that part of the metal ions (i.e. in the garnets: part of the “A” ions) in the luminescent material is replaced by Ce. For instance, in the case of (Y₁₋ₓLuₓ)₃Al₅O₁₂:Ce, part of Y and/or Lu is replaced by Ce. This is known to the person skilled in the art. Ce will replace A in general for not more than 10%; in general, the Ce concentration will be in the range of 0.1 to 4%, especially 0.1 to 2% (relative to A). Assuming 1% Ce and 10% Y, the full correct formula could be (Y_{0.1}Lu_{0.89}Ce_{0.01})₃Al₅O₁₂. Ce in garnets is substantially or only in the trivalent state, as is known to the person skilled in the art.

In embodiments, the luminescent material (thus) comprises A₃B₅O₁₂ wherein in specific embodiments at maximum 10% of B—O may be replaced by Si—N.

In specific embodiments the luminescent material comprises (Yₓ₁A′ₓ₂Ceₓ₃)₃(Al_{y1}B′_{y2})₅O₁₂, wherein x1+x2+x3=1, wherein x3>0, wherein 0<x2+x3≤0.2, wherein y1+y2=1, wherein especially 0≤y2≤0.2, wherein A′ comprises one or more elements selected from the group consisting of lanthanides, and wherein B′ comprises one or more elements selected from the group consisting of Ga, In and Sc. In embodiments, x3 is selected from the range of 0.001-0.1. In the present invention, especially x1>0, such as >0.2, like at least 0.8. Garnets with Y may provide suitable spectral power distributions.

In specific embodiments at maximum 10% of B—O may be replaced by Si—N. Here, B in B—O refers to one or more of Al, Ga, In and Sc (and O refers to oxygen); in specific embodiments B—O may refer to Al—O. As indicated above, in specific embodiments x3 may be selected from the range of 0.001-0.04. Especially, such luminescent materials may have a suitable spectral distribution (see however below), have a relatively high efficiency, have a relatively high thermal stability, and allow a high CRI (optionally in combination with (the) light of other sources of light as described herein). Hence, in specific embodiments A may be selected from the group consisting of Lu and Gd. Alternatively or additionally, B may comprise Ga. Hence, in embodiments the luminescent material comprises (Yₓ₁(Lu,Gd)ₓ₂Ceₓ₃)₃(Al_{y1}Ga_{y2})₅O₁₂, wherein Lu and/or Gd may be available. Even more especially, x3 is selected from the range of 0.001-0.1, wherein 0<x2+x3≤0.1, and wherein 0≤y2≤0.1. Further, in specific embodiments, at maximum 1% of B—O may be replaced by Si—N. Here, the percentage refers to moles (as known in the art); see e.g. also EP3149108. In yet further specific embodiments, the luminescent material comprises (Yₓ₁Ceₓ₃)₃Al₅O₁₂, wherein x1+x3=?1, and wherein 0<x3≤0.2, such as 0.001-0.1.

In specific embodiments, the light generating device may only include luminescent materials selected from the type of cerium comprising garnets. In even further specific embodiments, the light generating device includes a single type of luminescent materials, such as (Yₓ₁A′ₓ₂Ceₓ₃)₃(Al_{y1}B′_{y2})₅O₁₂. Hence, in specific embodiments the light generating device comprises luminescent material, wherein at least 85 weight %, even more especially at least about 90 wt. %, such as yet even more especially at least about 95 weight % of the luminescent material comprises (Yₓ₁A′ₓ₂Ceₓ₃)₃(Al_{y1}B′_{y2})₅O₁₂. Here, wherein A′ comprises one or more elements selected from the group consisting of lanthanides, and wherein B′ comprises one or more elements selected from the group consisting of Ga, In and Sc, wherein x1+x2+x3=1, wherein x3>0, wherein 0<x2+x3≤0.2, wherein y1+y2=1, wherein 0≤y2≤0.2. Especially, x3 is selected from the range of 0.001-0.1. Note that in embodiments x2=0. Alternatively or additionally, in embodiments y2=0.

In specific embodiments, A may especially comprise at least Y, and B may especially comprise at least Al.

Alternatively or additionally, wherein the luminescent material may comprises a luminescent material of the type A₃Si₆N₁₁:Ce³⁺, wherein A comprises one or more of Y, La, Gd, Tb and Lu, such as in embodiments one or more of La and Y.

In embodiments, the luminescent material may alternatively or additionally comprise one or more of MS:Eu²⁺ and/or M₂Si₅N₈:Eu²⁺ and/or MAlSiN₃:Eu²⁺ and/or Ca₂AlSi₃O₂N₅:Eu²⁺, etc., wherein M comprises one or more of Ba, Sr and Ca, especially in embodiments at least Sr. Hence, in embodiments, the luminescent may comprise one or more materials selected from the group consisting of (Ba,Sr,Ca)S:Eu, (Ba,Sr,Ca)AlSiN₃:Eu and (Ba,Sr,Ca)₂Si₅N₈:Eu. In these compounds, europium (Eu) is substantially or only divalent, and replaces one or more of the indicated divalent cations. In general, Eu will not be present in amounts larger than 10% of the cation; its presence will especially be in the range of about 0.5 to 10%, more especially in the range of about 0.5 to 5% relative to the cation(s) it replaces. The term “:Eu”, indicates that part of the metal ions is replaced by Eu (in these examples by Eu²⁺). For instance, assuming 2% Eu in CaAlSiN₃:Eu, the correct formula could be (Ca_{0.98}Eu_{0.02})AlSiN₃. Divalent europium will in general replace divalent cations, such as the above divalent alkaline earth cations, especially Ca, Sr or Ba. The material (Ba,Sr,Ca)S:Eu can also be indicated as MS:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Further, the material (Ba,Sr,Ca)₂Si₅N₈:Eu can also be indicated as M₂Si₅N₈:Eu, wherein M is one or more elements selected from the group consisting of barium (Ba), strontium (Sr) and calcium (Ca); especially, M comprises in this compound Sr and/or Ba. In a further specific embodiment, M consists of Sr and/or Ba (not taking into account the presence of Eu), especially 50 to 100%, more especially 50 to 90% Ba and 50 to 0%, especially 50 to 10% Sr, such as Ba_{1.5}Sr_{0.5}Si₅N₈:Eu (i.e. 75% Ba; 25% Sr). Here, Eu is introduced and replaces at least part of M, i.e. one or more of Ba, Sr, and Ca). Likewise, the material (Ba,Sr,Ca)AlSiN₃:Eu can also be indicated as MAlSiN₃:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Eu in the above indicated luminescent materials is substantially or only in the divalent state, as is known to the person skilled in the art.

In embodiments, a red luminescent material may comprise one or more materials selected from the group consisting of (Ba,Sr,Ca)S:Eu, (Ba,Sr,Ca)AlSiN₃:Eu and (Ba,Sr,Ca)₂Si₅N₈:Eu. In these compounds, europium (Eu) is substantially or only divalent, and replaces one or more of the indicated divalent cations. In general, Eu will not be present in amounts larger than 10% of the cation; its presence will especially be in the range of about 0.5 to 10%, more especially in the range of about 0.5 to 5% relative to the cation(s) it replaces. The term “:Eu”, indicates that part of the metal ions is replaced by Eu (in these examples by Eu²⁺). For instance, assuming 2% Eu in CaAlSiN₃:Eu, the correct formula could be (Ca_{0.98}Eu_{0.02})AlSiN₃. Divalent europium will in general replace divalent cations, such as the above divalent alkaline earth cations, especially Ca, Sr or Ba.

The material (Ba,Sr,Ca)S:Eu can also be indicated as MS:Eu, wherein Mis one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca).

Further, the material (Ba,Sr,Ca)₂Si₅N₈:Eu can also be indicated as M₂Si₅N₈:Eu, wherein Mis one or more elements selected from the group consisting of barium (Ba), strontium (Sr) and calcium (Ca); especially, M comprises in this compound Sr and/or Ba. In a further specific embodiment, M consists of Sr and/or Ba (not taking into account the presence of Eu), especially 50 to 100%, more especially 50 to 90% Ba and 50 to 0%, especially 50 to 10% Sr, such as Ba_{1.5}Sr_{0.5}Si₅N₈:Eu (i.e. 75% Ba; 25% Sr). Here, Eu is introduced and replaces at least part of M, i.e. one or more of Ba, Sr, and Ca).

Likewise, the material (Ba,Sr,Ca)AlSiN₃:Eu can also be indicated as MAlSiN₃:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca).

Eu in the above indicated luminescent materials is substantially or only in the divalent state, as is known to the person skilled in the art.

Blue luminescent materials may comprise YSO (Y₂SiO₅:Ce³⁺), or similar compounds, or BAM (BaMgAl₁₀O₁₇:Eu²⁺), or similar compounds.

The term “luminescent material” herein especially relates to inorganic luminescent materials.

Alternatively or additionally, also other luminescent materials may be applied. For instance quantum dots and/or organic dyes may be applied and may optionally be embedded in transmissive matrices like e.g. polymers, like PMMA, or polysiloxanes, etc, etc.

Quantum dots are small crystals of semiconducting material generally having a width or diameter of only a few nanometers. When excited by incident light, a quantum dot emits light of a color determined by the size and material of the crystal. Light of a particular color can therefore be produced by adapting the size of the dots. Most known quantum dots with emission in the visible range are based on cadmium selenide (CdSe) with a shell such as cadmium sulfide (CdS) and zinc sulfide (ZnS). Cadmium free quantum dots such as indium phosphide (InP), and copper indium sulfide (CuInS₂) and/or silver indium sulfide (AgInS₂) can also be used. Quantum dots show very narrow emission band and thus they show saturated colors. Furthermore the emission color can easily be tuned by adapting the size of the quantum dots. Any type of quantum dot known in the art may be used in the present invention. However, it may be preferred for reasons of environmental safety and concern to use cadmium-free quantum dots or at least quantum dots having a very low cadmium content.

Instead of quantum dots or in addition to quantum dots, also other quantum confinement structures may be used. The term “quantum confinement structures” should, in the context of the present application, be understood as e.g. quantum wells, quantum dots, quantum rods, tripods, tetrapods, or nanowires, etcetera.

Organic phosphors can be used as well. Examples of suitable organic phosphor materials are organic luminescent materials based on perylene derivatives, for example compounds sold under the name Lumogen® by BASF. Examples of suitable compounds include, but are not limited to, Lumogen® Red F305, Lumogen® Orange F240, Lumogen® Yellow F083, and Lumogen® F170.

Different luminescent materials may have different spectral power distributions of the respective luminescent material light. Alternatively or additionally, such different luminescent materials may especially have different color points (or dominant wavelengths).

As indicated above, other luminescent materials may also be possible. Hence, in specific embodiments the luminescent material is selected from the group of divalent europium containing nitrides, divalent europium containing oxynitrides, divalent europium containing silicates, cerium comprising garnets, and quantum structures. Quantum structures may e.g. comprise quantum dots or quantum rods (or other quantum type particles) (see above). Quantum structures may also comprise quantum wells. Quantum structures may also comprise photonic crystals.

Especially, the two or more luminescent materials comprise (i) a first luminescent material and a third luminescent material. Optionally, the two or more luminescent materials may also comprise a second luminescent material. The terms “first luminescent material”, “second luminescent material”, and “third luminescent material” may refer to luminescent materials complying with respective conditions. Hence, in embodiments the term “first luminescent material” may refer to one or more first luminescent materials, and may in a specific embodiment refer to essentially a single type of first luminescent material. Likewise, in embodiments the term “second luminescent material” may refer to one or more second luminescent materials, and may in a specific embodiment refer to essentially a single type of second luminescent material. Likewise, in embodiments the term “third luminescent material” may refer to one or more third luminescent materials, and may in a specific embodiment refer to essentially a single type of third luminescent material.

Especially, the first luminescent material may be configured to convert at least part of the device light into first luminescent material light having spectral power within the green-yellow wavelength range.

The phrase “within the green-yellow wavelength range”, and similar phrases, may indicate that there is spectral intensity in the green wavelength range, such as an emission band or line exclusively in the green wavelength range, or in the yellow wavelength range, such as an emission band or line exclusively in the yellow wavelength range, or in both the green wavelength range and the yellow wavelength range, such as an emission band (or line) having at least part of its spectral intensity in the green wavelength range and at least part of its spectral intensity in the yellow wavelength range. Likewise, this may apply to other ranges including multiple colors mentioned herein (e.g. the orange-red wavelength range). Further, in specific embodiments, the phrase “within the green-yellow wavelength range”, and similar phrases, may indicate that the luminescent material light may have a centroid wavelength in the green-yellow wavelength range. However, this is not necessarily the case, a luminescent material providing spectral power in the indicated wavelength range and outside the indicated wavelength range may also be applied. This may especially apply to the second luminescent material light.

The terms “blue light” or “blue emission”, and similar terms, may especially relate to light having a wavelength in the range of about 440-490 nm (including some violet and cyan hues). In specific embodiments, the blue light may have a centroid wavelength in the 440-490 nm range. The terms “green light” or “green emission”, and similar terms, may especially relate to light having a wavelength in the range of about 490-560 nm. In specific embodiments, the green light may have a centroid wavelength in the 490-560 nm range. The terms “yellow light” or “yellow emission”, and similar terms, may especially relate to light having a wavelength in the range of about 560-590 nm. In specific embodiments, the yellow light may have a centroid wavelength in the 560-590 nm range. The terms “orange light” or “orange emission”, and similar terms, may especially relate to light having a wavelength in the range of about 590-620 nm. In specific embodiments, the orange light may have a centroid wavelength in the 590-620 nm range. The terms “red light” or “red emission”, and similar terms, may especially relate to light having a wavelength in the range of about 620-750 nm. In specific embodiments, the red light may have a centroid wavelength in the 620-750 nm range. The terms “cyan light” or “cyan emission”, and similar terms, especially relate to light having a wavelength in the range of about 490-520 nm. In specific embodiments, the cyan light may have a centroid wavelength in the 490-520 nm range. The terms “amber light” or “amber emission”, and similar terms, may especially relate to light having a wavelength in the range of about 585-605 nm, such as about 590-600 nm. In specific embodiments, the amber light may have a centroid wavelength in the 585-605 nm range. The phrase “light having one or more wavelengths in a wavelength range” and similar phrases may especially indicate that the indicated light (or radiation) has a spectral power distribution with at least intensity or intensities at these one or more wavelengths in the indicate wavelength range. For instance, a blue emitting solid state light source will have a spectral power distribution with intensities at one or more wavelengths in the 440-495 nm wavelength range. The terms “violet light” or “violet emission”, and similar terms, may especially relate to light having a wavelength in the range of about 380-440 nm. In specific embodiments, the violet light may have a centroid wavelength in the 380-440 nm range.

The term “centroid wavelength”, also indicated as λc, is known in the art, and refers to the wavelength value where half of the light energy is at shorter and half the energy is at longer wavelengths; the value is stated in nanometers (nm). It is the wavelength that divides the integral of a spectral power distribution into two equal parts as expressed by the formula λc=Σλ*I(λ)/(ΣI(λ)), where the summation is over the wavelength range of interest, and I(λ) is the spectral energy density (i.e. the integration of the product of the wavelength and the intensity over the emission band normalized to the integrated intensity). The centroid wavelength may e.g. be determined at operation conditions.

Hence, the term “green-yellow wavelength range” may especially refer to the wavelength range of 490-590 nm. Further, the first luminescent material light may have a full width half maximum of at least 40 nm, more especially at least 50 nm. Further, the first luminescent material light may have a color point u′_{yellow}, v′_{yellow}. Hence, the first luminescent material may especially be a broad band emitter. Especially, the first luminescent material may have a centroid wavelength within the green-yellow wavelength range. Especially, in embodiments the first luminescent material light may have a centroid wavelength in the green-yellow wavelength range.

The color points indicated with u′,v′ especially refer to the CIE 1976 color points (see ISO CIE 11664-5: Colorimetry—Part5: CIE 1976 L*u*v* color space and u′, v′ uniform chromaticity scale diagram).

Especially, the optional second luminescent material may be configured to convert at least part of the device light into second luminescent material light having spectral power within the orange-red wavelength range. The term “orange-red wavelength range” may especially refer to the wavelength range of 590-780 nm. Further, the second luminescent material light may have a full width half maximum of at least 40 nm, more especially at least 50 nm. Yet, the second luminescent material light may have a color point u′_{red}, v′_{red}. Hence, the second luminescent material may especially be a broad band emitter. Especially, the second luminescent material may have a centroid wavelength within the orange-red wavelength range, more especially in the wavelength range of 590-680 nm. Especially, in embodiments the second luminescent material light may have a centroid wavelength in the orange-red wavelength range, though this is not necessarily the case. Second luminescent material having substantial intensity in the yellow wavelength range may however also be applied, when of course also having spectral power in the orange and/or red wavelength range.

Especially, the third luminescent material may be configured to convert at least part of the device light into third luminescent material light within the orange-red wavelength range. Especially, in embodiments the third luminescent material light may have a centroid wavelength in the orange-red wavelength range. In embodiments, the centroid wavelength of the second luminescent material light, if available, is smaller than the centroid wavelength of the third luminescent material light. For instance, the difference may be at least about 10 nm, more especially at least about 20 nm, such as selected from the range of 20-100 nm.

In embodiments, the third luminescent material comprises M′ₓM₂₋₂ₓAX₆ doped with tetravalent manganese, wherein M′ comprises an alkaline earth cation, wherein M comprises a cation, and x is in the range of 0-1, wherein A comprises a tetravalent cation, wherein X comprises a monovalent anion, at least comprising fluorine. Especially, the third luminescent material may be a narrow band emitter or line emitter. Tetravalent manganese may emit within the orange-red wavelength range with emission lines at room temperature having a FWHM of less than 50 nm, or even less than 40 nm, well-known for Mn⁴⁺ forbidden ²E_{g}→⁴A_{2g} transitions.

A luminescent material of the type M′ₓM₂₋₂ₓAX₆ doped with tetravalent manganese is amongst others described in WO2013121355A1, which is herein incorporated by reference. Passages from WO2013121355A1 are also copied herein.

Herein, M′ₓM₂₋₂ₓAX₆ doped with tetravalent manganese, may further also shortly be indicated as “phosphor”, i.e. the phrase “phosphor comprising M′ₓM₂₋₂ₓAX₆ doped with tetravalent manganese” may in an embodiment also be read as M′ₓM₂₋₂ₓAX₆ doped with tetravalent manganese phosphor, or (tetravalent) Mn-doped M′ₓM₂₋₂ₓAX₆ phosphor, or shortly “phosphor”.

Relevant alkaline cations (M) are sodium (Na), potassium (K) and rubidium (Rb). Optionally, also lithium (Li) and/or cesium (Cs) may be applied. In a preferred embodiment, M comprises at least potassium. In yet another embodiment, M comprises at least rubidium. The phrase “wherein M comprises at least potassium” indicates for instance that of all M cations in a mole M′ₓM₂₋₂ₓAX₆, a fraction comprises K+ and an optionally remaining fraction comprises one or more other monovalent (alkaline) cations (see also below). In another preferred embodiment, M comprises at least potassium and rubidium. Optionally, the M′ₓM₂₋₂ₓAX₆ luminescent material has the hexagonal phase. In yet another embodiment, the M′ₓM₂₋₂ₓAX₆ luminescent material has the cubic phase.

Relevant alkaline earth cations (M′) are magnesium (Mg), strontium (Sr), calcium (Ca) and barium (Ba), especially one or more of Sr and Ba.

In an embodiment, a combination of different alkaline cations may be applied. In yet another embodiment, a combination of different alkaline earth cations may be applied. In yet another embodiment, a combination of one or more alkaline cations and one or more alkaline earth cations may be applied. For instance, KRb_{0.5}Sr_{0.25}AX₆ might be applied. As indicated above, x may be in the range of 0-1, especially x<1. In an embodiment, x=0.

The term “tetravalent manganese” refers to Mn⁴⁺. This is a well-known luminescent ion. In the formula as indicated above, part of the tetravalent cation A (such as Si) is being replaced by manganese. Hence, M′ₓM₂₋₂ₓAX₆ doped with tetravalent manganese may also be indicated as M′ₓM₂₋₂ₓA₁₋ₘMnₘX₆. The mole percentage of manganese, i.e. the percentage it replaces the tetravalent cation A will in general be in the range of 0.1-15%, especially 1-12%, i.e. m is in the range of 0.001-0.15, especially in the range of 0.01-0.12.

A comprises a tetravalent cation, and preferably at least comprises silicon. A may optionally (further) comprise one or more of titanium (Ti), germanium (Ge), stannum (Sn) and zinc (Zn). Preferably, at least 80%, even more preferably at least 90%, such as at least 95% of M consists of silicon. Hence, in a specific embodiment, M′ₓM₂₋₂ₓAX₆ may also be described as M′ₓM₂₋₂ₓA_{1-m-t-g-s-zr}MnₘTiₜGe_{g}SnₛZr_{zr}X₆, wherein m and x are as indicated above, and wherein t,g,s,zr are each individually preferably in the range of 0-0.2, especially 0-0.1, even more especially 0-0.05, wherein t+g+s+zr is smaller than 1, especially equal to or smaller than 0.2, preferably in the range of 0-0.2, especially 0-0.1, even more especially 0-0.05, and wherein A is especially Si. X is preferably fluorine (F).

As indicated above, M relates to monovalent cations, but preferably at least comprises potassium and/or rubidium. Other monovalent cations that may further be comprised by M can be selected from the group consisting of lithium (Li), sodium (Na), cesium (Cs) and ammonium (NH₄⁺). In an embodiment, preferably at least 80% (i.e. 80% of all moles of the type M), even more preferably at least 90%, such as 95% of M consists of potassium and/or rubidium. Especially, in these embodiments x is thus zero.

Hence, in a specific embodiment, M′ₓM₂₋₂ₓAX₆ can also be described as (K_{1-r-l-n-c-nh}RbᵣLiₗNaₙCs_{c}(NH₄)ₙₕ)₂AX₆, wherein r is in the range of 0-1, wherein l,n,c,nh are each individually preferably in the range of 0-1, preferably 0-0.2, especially 0-0.1, even more especially 0-0.05, and wherein r+l+n+c+nh is in the range of 0-1, especially l+n+c+nh is smaller than 1, especially equal to or smaller than 0.2, preferably in the range of 0-0.2, especially 0-0.1, even more especially 0-0.05. X is preferably fluorine (F).

As indicated above, instead of or in addition to the alkaline cation(s), also one or more alkaline earth cations may be present. Hence, in a specific embodiment, M′ₓM₂₋₂ₓAX₆ can also be described as Mg_{mg}Ca_{ca}SrₛᵣBa_{ba}(KₖRbᵣLiₗNaₙCs_{c}(NH₄)ₙₕ)₂AX₆, with k, r, 1, n, c, nh each individually being in the range of 0-1, wherein mg, ca, sr, ba are each individually in the range of 0-1, and wherein mg+ca+sr+ba+k+r+l+n+c+nh=1. In embodiments, k=1, and the others (mg, ca, sr, ba, r, 1, n, c, nh) are zero.

As indicated above, X relates to a monovalent anion, but at least comprises fluorine. Other monovalent anions that may optionally be present may be selected from the group consisting of chlorine (Cl), bromine (Br), and iodine (I). Preferably, at least 80%, even more preferably at least 90%, such as 95% of X consists of fluorine. Hence, in a specific embodiment, M′ₓM₂₋₂ₓAX₆ can also be described as M′ₓM₂₋₂ₓA(F_{1-cl-b-i}Cl_{cl}Br_{b}Iᵢ)₆, wherein cl,b,i are each individually preferably in the range of 0-0.2, especially 0-0.1, even more especially 0-0.05, and wherein cl+b+i is smaller than 1, especially equal to or smaller than 0.2, preferably in the range of 0-0.2, especially 0-0.1, even more especially 0-0.05. Especially, X essentially consists of F (fluorine).

Hence, M′ₓM₂₋₂ₓAX₆ can also be described as (K_{1-r-l-n-c-nh}RbᵣLiₗNaₙCs_{c}(NH₄)ₙₕ)₂Si_{1-m-t-g-s-zr}MnₘTiₜGe_{g}SnₛZr_{zr}(F_{1-cl-b-i}Cl_{cl}Br_{b}Iᵢ)₆, with the values for r,l,n,c,nh,m,t,g,s,zr,cl,b,i as indicated above. X is preferably fluorine (F).

Even more especially, M′ₓM₂₋₂ₓAX₆ can also be described as Mg_{mg}Ca_{ca}SrₛᵣBa_{ba}(KₖRbᵣLiₗNaₙCs_{c}(NH₄)ₙₕ)₂Si_{1-m-t-g-s-zr}MnₘTiₜGe_{g}SnₛZr_{zr}(F_{1-cl-b-i}Cl_{cl}Br_{b}Iᵢ)₆, with k, r, l, n, c, nh each individually being in the range of 0-1, wherein mg, ca, sr, ba are each individually in the range of 0-1, wherein mg+ca+sr+ba+k+r+l+n+c+nh=1, and with the values for m,t,g,s,zr,cl,b,i as indicated above. X is preferably fluorine (F).

In an embodiment, M′ₓM₂₋₂ₓAX₆ comprises K₂SiF₆ (indicated herein also as KSiF system). As indicated above, in another preferred embodiment, M′ₓM₂₋₂ₓAX₆ comprises KRbSiF₆ (i.e. r=0.5 and l,n,c,nh,t,g,s,zr,cl,b,i are 0) (herein also indicated as K,Rb system). As indicated above, part of silicon is replaced by manganese (i.e. the formula may also be described as K₂Si₁₋ₘMnₘF₆ or KRbSi₁₋ₘMnₘF₆, with m as indicated above, or as KRbSiF₆:Mn and K₂SiF₆:Mn, respectively). As manganese replaces part of a host lattice ion and has a specific function, it is also indicated as “dopant” or “activator”. Hence, the hexafluorosilicate is doped or activated with manganese (Mn⁴⁺).

In specific embodiments, the luminescent material may comprise (K,Rb)₂SiF₆:Mn⁴⁺. Alternatively or additionally, in embodiments the third luminescent material may comprise K₂SiF₆:Mn⁴⁺. Alternatively or additionally, in embodiments the third luminescent material may comprise K₂TiF₆:Mn⁴⁺. In embodiments, the third luminescent material may comprise K₂(Si, Ti)F₆:Mn⁴⁺. As can be derived from the above, “Si, Ti” may indicate one or more of Si and Ti.

The luminescent material may also be coated, as also described in WO2013121355A1.

In embodiments, the third luminescent material may have a color point selected from the ranges of 0.52≤u′≤0.54 and 0.50≤v′≤0.53 (such as 0.51≤v′≤0.53). Herein, it is indicated that the first luminescent material and/or the second luminescent material and/or the third luminescent material are configured to convert at least part of the device light. It is herein not excluded that one or more of these luminescent materials may also absorb part of the luminescent material light of one or more of the others of these luminescent materials.

The light generating system is configured to generate system light. In embodiments, in an operational mode, the system light may comprise (i) at least part of the device light, (ii) at least part of the first luminescent material light, and (iii) at least part of the third luminescent material light. Other compositions may also be possible, especially when two or more light generating devices are applied, and/or when (also) light generating devices are applied different from the light generating device. Especially, however, in embodiments the light generating system is configured to generate system light comprising (i) at least part of the device light, (ii) at least part of the first luminescent material light, and (iii) at least part of the third luminescent material light.

In embodiments, the system may be configured such that the system light may have one or more of (i) an R_{f} value of at least 85, (ii) an R_{f,h1} value of at least 85, (iii) an R_{g} value of at least 95, and (iv) an R_{cs,h1} value of at least −1%.

Especially, the two or more luminescent materials and the light generating device (and optionally further light generating devices) may be (configured and) selected such that the system light may be of a high quality, and may comply with P1F3 or higher conditions. P1F3 conditions are described in TM-30 (2020) standard ANSI/IES TM-30-20: IES Method for Evaluating Light Source Color Rendition and may involve R_{f}, R_{f,h1}, R_{g}, and R_{cs,h1}. Herein, R_{f} may refer to the fidelity (average color difference of objects under Ref. and Test-source), R_{f,h1} may refer to the fidelity for Hue-bin 1 (red colors), R_{g} may refer to the gamut index (saturation of colors), and R_{cs,h1} may refer to the color saturation of Hue-bin 1. Further, especially the system light may have a correlated color temperature (CCT) selected from the range of 1800-6500 K. Therefore, in embodiments the system may be configured such that the system light is white light having a correlated color temperature (CCT) selected from the range of 1800-6500 K, an R_{f} value of at least 85, an R_{f,h1} value of at least 85, an R_{g} value of at least 95, and an R_{cs,h1} value of at least −1%, wherein R_{f}, R_{f,h1}, R_{g}, and R_{cs,h1} are defined according to TM-30 (2020) standard ANSI/IES TM-30-20: IES Method for Evaluating Light Source Color Rendition. Especially, the correlated color temperature (CCT) may be selected from the range of 2700-6500 K. Therefore, in embodiments the light generating device and two or more luminescent materials are selected and configured such that the system light is white light having a correlated color temperature (CCT) selected from the range of 1800-6500 K, and one or more of, especially all of: an R_{f} value of at least 85, an R_{f,h1} value of at least 85, an R_{g} value of at least 95, and an R_{cs,h1} value of at least −1%.

It appears that the system light may have these properties when the light generating device and the two or more luminescent materials, as defined herein, are selected. More especially, the system light may have these properties when specific conditions apply for the contribution of the third luminescent material light to the spectral power distribution of the system light. Here, two embodiments may be distinguished: (a) the two or more luminescent materials comprise the second luminescent material, and thus the system light may comprise the second luminescent material light, or (b) the two or more luminescent materials do not comprise the second luminescent material, and thus the system light does not comprise the second luminescent material light. A contribution to a spectral power distribution of the system light in the wavelength range of 380-780 nm by the third luminescent material light is herein defined as a fraction G.

In embodiments, the following may apply: (a) when the system light (also) comprises the second luminescent material light, the fraction G is selected from the range of a′*G′−a″*G′, wherein G′ complies with the following formula: G′=1.4421−2.904125*10⁻⁸*PWL−10.08921*u′_{Yellow}−0.5457286*u′_{Red}−1.074782*10⁻⁴*CCT+21.623*[u′_{Yellow}]²−1.639*[u′_{Red}]²+4.921703*10⁻⁹*[CCT]²+2.316461*10⁻⁷*[PWL*u′_{Red}]+7.268292*[u′_{Yellow}*u′_{Red}]+9.309924*10⁻⁵*[u′_{Red}*CCT], wherein a′=0.95 and a″=1.05, and wherein the fraction G is at least 0.05 and at maximum 0.2; or (b) when the system light does not comprise the second luminescent material light, the following applies: u′_{Yellow}≥a′″*(0.2546−0.000016*CCT), wherein a′″=0.95, and the fraction G is at least 0.05 and at maximum 0.2. Note that whether or not the second luminescent material light is comprised in the system light, the contribution to the spectral power distribution in the 380-780 nm wavelength range of the third luminescent material light may especially be selected from the range of 0.05-0.2. The parameters a′, a″, and a′″ in the formulas allow some freedom. The closer these parameters are to 1, the better the results may be. In specific embodiments, G may be selected from the range of 0.97*G′-1.03*G′ or u′_{Yellow}≥0.97*(0.2546−0.000016*CCT) (i.e. a′ and a′″ are 0.97 and a″ is 1.03). More especially, G may be selected from the range of 0.98*G′-1.02*G′ or u′_{Yellow}≥0.98*(0.2546−0.000016*CCT) (i.e. a′ and a′″ are 0.98 and a″ is 1.02). Yet even more especially, G may be selected from the range of 0.99*G′-1.01*G′ or u′_{Yellow}≥0.99*(0.2546−0.000016*CCT) (i.e. a′ and a′″ are 0.99 and a″ is 1.01). Hence, in embodiments G=G′ or u′_{Yellow}≥(0.2546−0.000016*CCT) (i.e. a′, a″, and a′″ are 1). In specific embodiments, the fraction G is at least 0.1 (and thus at maximum 0.2). Especially then, P1F3 or even higher conditions may be met, while maintaining a relatively high efficiency.

Especially, the first luminescent material may comprise a garnet luminescent material, such as described above. The first luminescent material may provide substantial spectral power within the green-yellow wavelength range in an efficient way. In embodiments, the first luminescent material may comprise a luminescent material of the type A₃B₅O₁₂:Ce, wherein A comprises one or more of Y, La, Gd, Tb and Lu, and wherein B comprises one or more of Al, Ga, In and Sc. Such luminescent materials are relatively broad band emitters, such as having a FWHM of at least about 40 nm, more especially at least about 50 nm. Especially, A may comprise one or more of Y, Gd, and Lu. Further, B may especially comprise Al, and optionally Ga. In specific embodiments, the first luminescent material comprises one or more of Lu₃B₅O₁₂:Ce³⁺, Y₃Al₅O₁₂:Ce³⁺, Y₃(Al,Ga)₅O₁₂:Ce³⁺, and (Gd, Y)₃B₅O₁₂:Ce (see further also below), especially the first luminescent material may comprise one or more of Lu₃Al₅O₁₂:Ce³⁺, Y₃Al₅O₁₂:Ce³⁺, Y₃(Al,Ga)₅O₁₂:Ce³⁺, and (Gd, Y)₃Al₅O₁₂:Ce.

Referring to the third luminescent material, as described also above, especially in embodiments for M′ₓM₂₋₂ₓAX₆ doped applies that x=0, M comprises one or more of K and Rb, and wherein X═F. Further, A may especially comprise Si (silicon).

In the absence of the second luminescent material, especially higher CCTs may be obtained, such as at least about 3800 K, like at least about 4000 K. Hence, in embodiments the system light does not comprise the second luminescent material light, and the correlated color temperature may be selected from the range of 4000-6500 K.

When the second luminescent material is not present, it may be desirable to apply a first luminescent material that may be relatively red shifted when compared to a first luminescent material that may be used in combination with the second luminescent material. Therefore, in embodiments the first luminescent material may be of the garnet type, but may especially comprise a relatively high Gd content and/or a relatively low Ga content and/or a relatively low Lu content. Therefore, in embodiments A in A₃B₅O₁₂:Ce comprises Gd and/or less than 10% Lu and/or wherein B in A₃B₅O₁₂:Ce comprises less than 10% Ga. Further, as indicated above, in such embodiments also a higher CCT, like at least 3800 K may be selected. Especially, in (such) embodiments the first luminescent material light may have a color point (u′_{yellow}, v′_{yellow}) selected from the ranges of 0.15≤u′≤0.200 and 0.555≤v′≤0.575.

In specific embodiments, the two or more luminescent materials consist of the first luminescent material and the third luminescent material. Hence, in such embodiments essentially no further contributions to the spectral power distribution are available than those of the first luminescent material and the third luminescent material (and of course the device light).

In other embodiments, the second luminescent material is present, and a contribution in the spectral power distribution of the second luminescent material light in the system light (in an operational mode) is available. Especially, in such embodiments the second luminescent material may comprise a divalent europium containing nitride. The second luminescent material may provide substantial spectral power within the orange-red wavelength range (and optionally also in one or more other wavelength ranges) in an efficient way. Such divalent europium containing nitride luminescent materials are relatively broad band emitters, such as having a FWHM of at least about 40 nm, more especially at least about 50 nm. Therefore, in embodiments the system light may comprise the second luminescent material light; wherein the second luminescent material may especially comprise one or more of M₂Si₅N₈:Eu²⁺, MAlSiN₃:Eu²⁺, and M₂AlSi₃O₂N₅:Eu²⁺, wherein M comprises one or more of Ba, Sr and Ca. Especially, in embodiments the second luminescent material may comprise MAlSiN₃:Eu²⁺; where M comprises at least Sr and Ca. For instance, at least 90% of M may consist of Sr and/or Ca. In embodiments, the second luminescent material may have a color point (u′_{red}, v′_{red}) selected from the ranges of 0.33≤u′≤0.48 and 0.525≤v′≤0.550.

Especially, in embodiments wherein the two or more luminescent materials comprise the first luminescent material, the second luminescent material, and the third luminescent material, one or more of the following may apply: (a) the first luminescent material has a color point (u′_{yellow}, v′_{yellow}) selected from the ranges of 0.135≤u′≤0.200 and 0.555≤v′≤0.575; (b) the second luminescent material has a color point (u′_{red}, v′_{red}) selected from the ranges of 0.33≤u′≤0.48 and 0.525≤v′≤0.550; and (c) the third luminescent material has a color point selected from the ranges of 0.52≤u′≤0.54 and 0.50≤v′≤0.53 (especially 0.51≤v′≤0.53). The latter color point, i.e. for the third luminescent material, may apply in general (as its color point is relatively independent from the composition of the third luminescent material), and thus also for embodiments not comprising the second luminescent material.

In specific embodiments, the two or more luminescent materials consist of the first luminescent material, the second luminescent material, and the third luminescent material. Hence, in such embodiments essentially no further contributions to the spectral power distribution are available than those of the first luminescent material, the second luminescent material, and the third luminescent material.

In embodiments, the spectral power distribution of the system light has the following contributions, see Table 1.

TABLE 1

| Wavelength range | min | max |
|---|---|---|
| 380-400 nm | 0% | 1% |
| 400-420 nm | 0% | 1% |
| 420-440 nm | 0% | 1% |
| 440-460 nm | 6% | 11% |
| 460-480 nm | 1% | 9% |
| 480-500 nm | 2% | 9% |
| 500-520 nm | 6% | 9% |
| 520-540 nm | 7% | 10% |
| 540-560 nm | 8% | 11% |
| 560-580 nm | 8% | 10% |
| 580-600 nm | 7% | 10% |
| 600-620 nm | 10% | 12% |
| 620-640 nm | 13% | 19% |
| 640-660 nm | 4% | 6% |
| 660-680 nm | 1% | 3% |
| 680-700 nm | 0% | 2% |
| 700-720 nm | 0% | 1% |
| 720-740 nm | 0% | 1% |
| 740-760 nm | 0% | 1% |
| 760-780 nm | 0% | 1% |

The contribution should be selected from the indicated ranges such, that a total of 100% is obtained.

In further embodiments, the spectral power distribution of the system light has the following contributions, see Table 2.

TABLE 2

| Wavelength range | min | max |
|---|---|---|
| 380-400 nm | 0% | 1% |
| 400-420 nm | 0% | 1% |
| 420-440 nm | 0% | 3% |
| 440-460 nm | 6% | 11% |
| 460-480 nm | 1% | 9% |
| 480-500 nm | 2% | 9% |
| 500-520 nm | 6% | 9% |
| 520-540 nm | 7% | 10% |
| 540-560 nm | 7% | 11% |
| 560-580 nm | 7% | 10% |
| 580-600 nm | 7% | 10% |
| 600-620 nm | 9% | 12% |
| 620-640 nm | 12% | 19% |
| 640-660 nm | 3% | 6% |
| 660-680 nm | 1% | 3% |
| 680-700 nm | 0% | 2% |
| 700-720 nm | 0% | 1% |
| 720-740 nm | 0% | 1% |
| 740-760 nm | 0% | 1% |
| 760-780 nm | 0% | 1% |

The contribution should be selected from the indicated ranges such, that a total of 100% is obtained.

According to a further aspect, the invention provides a light generating system comprising a light generating device and two or more luminescent materials, wherein:
the light generating device is configured to generate device light having a peak wavelength selected from the wavelength range of 440-465 nm; wherein the light generating device comprises a solid state light source;
the two or more luminescent materials comprise (i) a first luminescent material configured to convert at least part of the device light into first luminescent material light having spectral power within the green-yellow wavelength range, a full width half maximum of at least 50 nm, and a color point u′_{yellow}, v′_{yellow}, wherein the first luminescent material comprises a luminescent material of the type A₃B₅O₁₂:Ce³⁺, wherein A comprises one or more of Y, La, Gd, Tb and Lu, and wherein B comprises one or more of Al, Ga, In and Sc; (ii) optionally a second luminescent material configured to convert at least part of the device light into second luminescent material light having spectral power within the orange-red wavelength range, a full width half maximum of at least 50 nm, and a color point u′_{red}, v′_{red}, wherein the second luminescent material comprises one or more luminescent materials of the type MS:Eu²⁺, M₂Si₅N₈:Eu²⁺, MAlSiN₃:Eu²⁺ and Ca₂AlSi₃O₂N₅:Eu²⁺, wherein M comprises one or more of Ba, Sr and Ca; and (iii) a third luminescent material configured to convert at least part of the device light into third luminescent material light within the orange-red wavelength range, wherein the third luminescent material comprises M′ₓM₂₋₂ₓAX₆ doped with tetravalent manganese, wherein M′ comprises an alkaline earth cation, wherein M comprises a cation, and x is in the range of 0-1, wherein A comprises a tetravalent cation, wherein X comprises a monovalent anion, at least comprising fluorine;
the light generating system is configured to generate system light comprising (i) at least part of the device light, (ii) at least part of the first luminescent material light, and (iii) at least part of the third luminescent material light; wherein the system is configured such that the system light is white light having a correlated color temperature (CCT) selected from the range of 1800-6500 K,
wherein a contribution to a spectral power distribution of the system light in the wavelength range of 380-780 nm by the third luminescent material light is defined as a fraction G, and wherein the following applies:
   (a) when the system light (1001) comprises the second luminescent material light (221), the fraction G is selected from the range of 0.95*G′-1.05*G′, wherein G′ complies with the following formula:

$${G}^{′} = 1.4421 - 2.904125 * {10}^{- 8} * PWL - 10.08921 * {u}_{Yellow}^{′} - 0.5457286 * {u}_{R e d}^{′} - 1.074782 * {10}^{- 4} * CCT + 21.623 * {[ {u}_{Yellow}^{′} ]}^{2} - 1.639 * {[ {u}_{R e d}^{′} ]}^{2} + 4.9 \; 21703 * {10}^{- 9} * {[ CCT ]}^{2} + 2.3 \; 16461 * {10}^{- 7} * [ PWL * {u}_{R e d}^{′} ] + 7.268292 * [ {u}_{Yellow}^{′} * {u}_{R e d}^{′} ] + 9.3 \; 09924 * {10}^{- 5} * [ {u}_{Red}^{′} * CCT ]$$

and wherein the fraction G is at least 0.05 and at maximum 0.2; or
(b) when the system light does not comprise the second luminescent material light, the following applies: u′_{Yellow}≥0.95*(0.2546−0.000016*CCT), and the fraction G is at least 0.05 and at maximum 0.2; and
wherein the spectral power distribution of the system light has the following contributions:

| Wavelength range | min | max |
|---|---|---|
| 380-400 nm | 0% | 1% |
| 400-420 nm | 0% | 1% |
| 420-440 nm | 0% | 3% |
| 440-460 nm | 6% | 11% |
| 460-480 nm | 1% | 9% |
| 480-500 nm | 2% | 9% |
| 500-520 nm | 6% | 9% |
| 520-540 nm | 7% | 10% |
| 540-560 nm | 7% | 11% |
| 560-580 nm | 7% | 10% |
| 580-600 nm | 7% | 10% |
| 600-620 nm | 9% | 12% |
| 620-640 nm | 12% | 19% |
| 640-660 nm | 3% | 6% |
| 660-680 nm | 1% | 3% |
| 680-700 nm | 0% | 2% |
| 700-720 nm | 0% | 1% |
| 720-740 nm | 0% | 1% |
| 740-760 nm | 0% | 1% |
| 760-780 nm | 0% | 1% |

Further embodiments are provided according to claims 2-15.

The light generating system may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, (outdoor) road lighting systems, urban lighting systems, green house lighting systems, horticulture lighting, digital projection, or LCD backlighting. The light generating system (or luminaire) may be part of or may be applied in e.g. optical communication systems or disinfection systems.

The term “white light”, and similar terms, herein, is known to the person skilled in the art. It may especially relate to light having a correlated color temperature (CCT) between about 1800 K and 20000 K, such as between 2000 and 20000 K, especially 2700-20000 K, for general lighting especially in the range of about 2000-7000 K, such as in the range of 2700 K and 6500 K. In embodiments, e.g. for backlighting purposes, or for other purposes, the correlated color temperature (CCT) may especially be in the range of about 7000 K and 20000 K. Yet further, in embodiments the correlated color temperature (CCT) is especially within about 15 SDCM (standard deviation of color matching) from the BBL (black body locus), especially within about 10 SDCM from the BBL, even more especially within about 5 SDCM from the BBL. In embodiments, the white light herein has a CRI of at least 90, such as at least 92, more especially at least 94, like in embodiments even at least 95.

The terms “visible”, “visible light” or “visible emission” and similar terms refer to light having one or more wavelengths in the range of about 380-780 nm. Herein, UV may especially refer to a wavelength selected from the range of 190-380 nm, such as 200-380 nm.

The terms “light” and “radiation” are herein interchangeably used, unless clear from the context that the term “light” only refers to visible light. The terms “light” and “radiation” may thus refer to UV radiation, visible light, and IR radiation. In specific embodiments, especially for lighting applications, the terms “light” and “radiation” refer to (at least) visible light.

The term “controlling” and similar terms especially refer at least to determining the behavior or supervising the running of an element. Hence, herein “controlling” and similar terms may e.g. refer to imposing behavior to the element (determining the behavior or supervising the running of an element), etc., such as e.g. measuring, displaying, actuating, opening, shifting, changing temperature, etc. Beyond that, the term “controlling” and similar terms may additionally include monitoring. Hence, the term “controlling” and similar terms may include imposing behavior on an element and also imposing behavior on an element and monitoring the element. The controlling of the element can be done with a control system, which may also be indicated as “controller”. The control system and the element may thus at least temporarily, or permanently, functionally be coupled. The element may comprise the control system. In embodiments, the control system and element may not be physically coupled. Control can be done via wired and/or wireless control. The term “control system” may also refer to a plurality of different control systems, which especially are functionally coupled, and of which e.g. one control system may be a master control system and one or more others may be slave control systems. A control system may comprise or may be functionally coupled to a user interface.

The control system may also be configured to receive and execute instructions from a remote control. In embodiments, the control system may be controlled via an App on a device, such as a portable device, like a smartphone or iPhone, a tablet, etc. The device is thus not necessarily coupled to the lighting system, but may be (temporarily) functionally coupled to the lighting system.

Hence, in embodiments the control system may (also) be configured to be controlled by an App on a remote device. In such embodiments the control system of the lighting system may be a slave control system or control in a slave mode. For instance, the lighting system may be identifiable with a code, especially a unique code for the respective lighting system. The control system of the lighting system may be configured to be controlled by an external control system which has access to the lighting system on the basis of knowledge (input by a user interface of with an optical sensor (e.g. QR code reader) of the (unique) code. The lighting system may also comprise means for communicating with other systems or devices, such as on the basis of Bluetooth, Thread, WIFI, LiFi, ZigBee, BLE or WiMAX, or another wireless technology.

The system, or apparatus, or device may execute an action in a “mode” or “operation mode” or “mode of operation” or “operational mode”. The term “operational mode may also be indicated as “controlling mode”. Likewise, in a method an action or stage, or step may be executed in a “mode” or “operation mode” or “mode of operation” or “operational mode”. This does not exclude that the system, or apparatus, or device may also be adapted for providing another controlling mode, or a plurality of other controlling modes. Likewise, this may not exclude that before executing the mode and/or after executing the mode one or more other modes may be executed.

However, in embodiments a control system may be available, that is adapted to provide at least the controlling mode. Would other modes be available, the choice of such modes may especially be executed via a user interface, though other options, like executing a mode in dependence of a sensor signal or a (time) scheme, may also be possible. The operation mode may in embodiments also refer to a system, or apparatus, or device, which can only operate in a single operation mode (i.e. “on”, without further tunability).

Hence, in embodiments, the control system may control in dependence of one or more of an input signal of a user interface, a sensor signal (of a sensor), and a timer. The term “timer” may refer to a clock and/or a predetermined time scheme.

In yet a further aspect, the invention also provides a lamp or a luminaire comprising the light generating system as defined herein. The luminaire may further comprise a housing, optical elements, louvres, etc, etc. The lamp or luminaire may further comprise a housing enclosing the light generating system. The lamp or luminaire may comprise a light window in the housing or a housing opening, through which the system light may escape from the housing. In yet a further aspect, the invention also provides a projection device comprising the light generating system as defined herein. Especially, a projection device or “projector” or “image projector” may be an optical device that projects an image (or moving images) onto a surface, such as e.g. a projection screen. The projection device may include one or more light generating systems such as described herein. Hence, in an aspect the invention also provides a light generating device selected from the group of a lamp, a luminaire, a projector device, a disinfection device, a photochemical reactor, and an optical wireless communication device, comprising the light generating system as defined herein. The light generating device may comprise a housing or a carrier, configured to house or support, one or more elements of the light generating system. For instance, in embodiments the light generating device may comprise a housing or a carrier, configured to house or support one or more of the light generating devices and optionally the two or more luminescent materials.

Instead of the terms “lighting device” or “lighting system”, and similar terms, also the terms “light generating device” or “light generating system”, (and similar terms), may be applied. A lighting device or a lighting system may be configured to generate device light (or “lighting device light”) or system light (“or lighting system light”). As indicated above, the terms light and radiation may interchangeably be used.

The lighting device may comprise a light source. The device light may in embodiments comprise one or more of light source light and converted light source light (such as luminescent material light).

The lighting system may comprise a light source. The system light may in embodiments comprise one or more of light source light and converted light source light (such as luminescent material light).

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIGS. 1a-1b schematically depict some embodiments of the system;

FIGS. 2a-2c depict some spectral power distributions; and

FIG. 3 schematically depict some application embodiments.

The schematic drawings are not necessarily to scale.

### DETAILED DESCRIPTION OF THE EMBODIMENTS

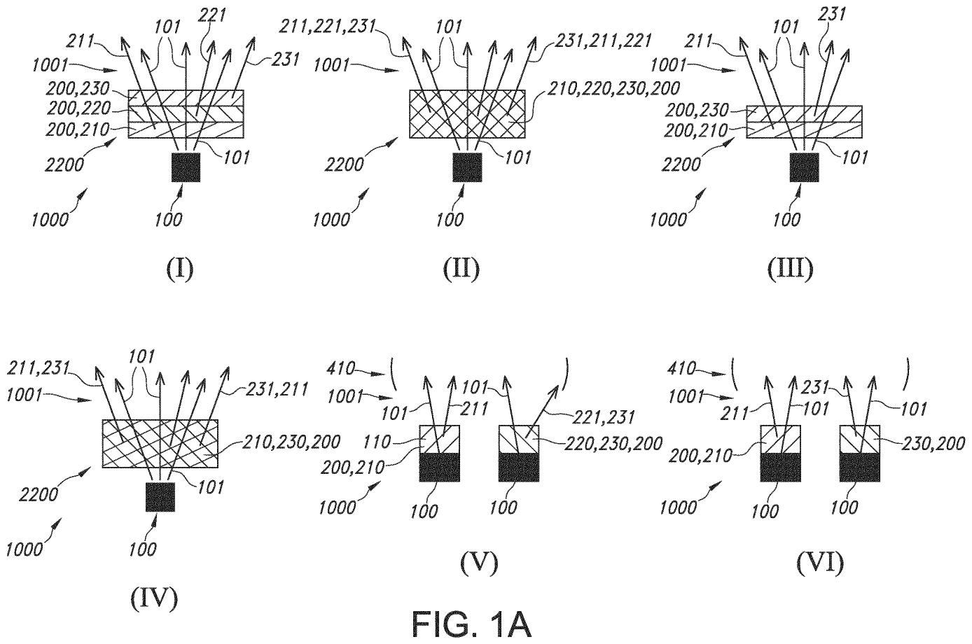

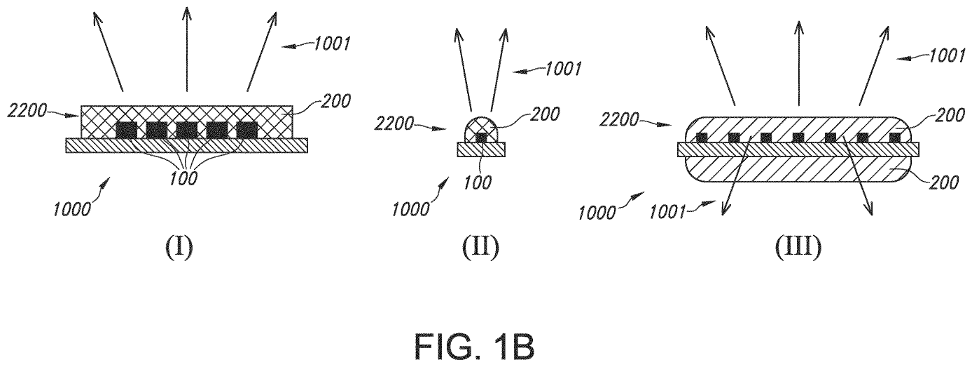

FIG. 1 schematically depicts embodiments of a light generating system 1000 comprising a light generating device 100 and two or more luminescent materials 200.

Especially, the light generating device 100 is configured to generate device light 101 having a peak wavelength selected from the wavelength range of 440-465 nm. In embodiments, the light generating device 100 comprises a solid state light source. In embodiments, the device light 101 may have a peak wavelength selected from the wavelength range of 445-460 nm.

Especially, the two or more luminescent materials 200 are configured to convert at least part of the device light into luminescent material light. The two or more luminescent materials 200 may comprise (i) a first luminescent material 210 configured to convert at least part of the device light 101 into first luminescent material light 211 having spectral power within the green-yellow wavelength range, a full width half maximum of at least 50 nm, and a color point u′_{yellow}, v′_{yellow}; (ii) optionally a second luminescent material 220 configured to convert at least part of the device light 101 into second luminescent material light 221 having spectral power within the orange-red wavelength range, a full width half maximum of at least 50 nm, and a color point u′_{red}, v′_{red}; and (iii) a third luminescent material 230 configured to convert at least part of the device light 101 into third luminescent material light 231 within the orange-red wavelength range, wherein the third luminescent material 230 comprises M′ₓM₂₋₂ₓAX₆ doped with tetravalent manganese, wherein M′ comprises an alkaline earth cation, wherein M comprises a cation, and x is in the range of 0-1, wherein A comprises a tetravalent cation, wherein X comprises a monovalent anion, at least comprising fluorine.

The light generating system 1000 is especially configured to generate system light 1001 comprising (i) at least part of the first device light 101, (ii) at least part of the first luminescent material light 211, and (iii) at least part of the third luminescent material light 231. In embodiments, the correlated color temperature CCT of the system light 1001 may be selected from the range of 2700-6500 K.

In embodiments, the first luminescent material 210 may comprise a luminescent material of the type A₃B₅O₁₂:Ce, wherein A comprises one or more of Y, La, Gd, Tb and Lu, and wherein B comprises one or more of Al, Ga, In and Sc. Especially, in embodiments the first luminescent material 210 may comprise one or more of Lu₃B₅O₁₂:Ce³⁺, Y₃Al₅O₁₂:Ce³⁺, Y₃Al, Ga₅O₁₂:Ce³⁺, and Gd, Y₃B₅O₁₂:Ce.

In embodiments, in relation to the third luminescent material 230, for M′ₓM₂₋₂ₓAX₆ doped may apply that x=0, M comprises one or more of K and Rb, and wherein X═F.

In embodiments, the second luminescent material 220 may comprise one or more of M₂Si₅No:Eu²⁺, MAlSiN₃:Eu²⁺, and M₂AlSi₃O₂N₅:Eu²⁺, wherein M comprises one or more of Ba, Sr and Ca. Especially, in embodiments the second luminescent material 220 may comprise MAlSiN₃:Eu²⁺; where M comprises at least Sr and Ca.

In embodiments, the first luminescent material 210 may have a color point selected from the ranges of 0.135≤u′≤0.200 and 0.555≤v′≤0.575; the second luminescent material 220 may have a color point selected from the ranges of 0.33≤u′≤0.48 and 0.525≤v′≤0.550; and the third luminescent material 230 may have a color point selected from the ranges of 0.52≤u′≤0.54 and 0.51≤v′≤0.53.

As schematically depicted, the system 1000 may comprise one or more a light generating devices 100 and a luminescent element 2200, wherein the luminescent element 2200 comprises the first luminescent material 210, (optionally) the second luminescent material 220, and the third luminescent material 230. Especially, the luminescent element 2200 may be configured downstream of the one or more a light generating devices 100. In specific embodiments, the luminescent element 2200 may be configured in contact with the one or more a light generating devices 100.

FIG. 1a very schematically depicts a number of embodiments. Embodiments I-IV schematically show embodiments based on the arrangement that all luminescent materials 200 are pumped with the same device light 101 and by the same device 100. Optionally, the device 100 may refer to a plurality of identical devices all pumping the same luminescent materials 200, and not necessarily individually controllable.

Embodiments I and III refer to luminescent element 2200 comprising multilayers, with in embodiment I the three luminescent materials 210,220,230, and in embodiment III the two luminescent materials 210,230. Note that the sequence of the luminescent materials 200 may differ from the displayed sequence. Embodiments II and IV related to the same luminescent materials 200 as embodiments I and III, respectively, but then not comprised as multi-layer but as mixture. Hence, the system light 1001 in embodiments I and II comprises the first device light 101, the first luminescent material light 211, the second luminescent material light 221, and the third luminescent material light 231. Yet, the system light 1001 in embodiments III and IV comprises the first device light 101, the first luminescent material light 211, and the third luminescent material light 231.

Embodiments V and VI are displayed to show that optionally different pumps may be used to pump different (combinations of) luminescent materials 200. For instance, the light generating devices 100 in embodiments V and VI may be individually controlled. In this way the color point of the system light 1001 may be controlled.

Reference 410 refers to an optical element, which may be configured downstream of the luminescent materials 200.

The term “optics” may especially refer to (one or more) optical elements. Hence, the terms “optics” and “optical elements” may refer to the same items. The optics may include one or more or mirrors, reflectors, collimators, lenses, prisms, diffusers, phase plates, polarizers, diffractive elements, gratings, dichroics, arrays of one or more of the afore-mentioned, etc. Alternatively or additionally, the term “optics” may refer to a holographic element or a mixing rod. In embodiments, the optics may include one or more of beam expander optics and zoom lens optics. See further above for examples of optics. In embodiments, the optics may comprise an integrator, like a “Koehler integrator” (or “Köhler integrator”). Here, the optical element 410 may alternatively or additionally comprise a diffusor.

FIG. 1b schematically depict some further embodiments. For instance, the light generating system 1000 may comprise a chip-on-board (I), a LED package (II), or a LED filament (III), comprising the light generating device 100 and the two or more luminescent materials 200.

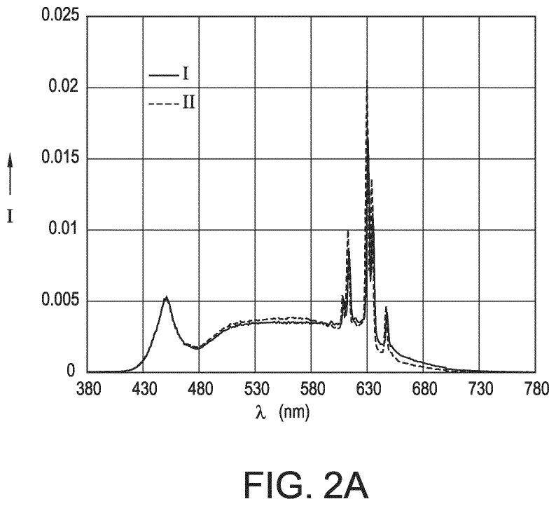

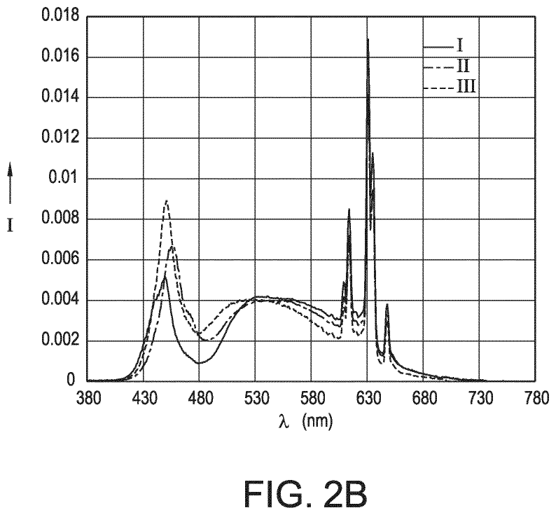

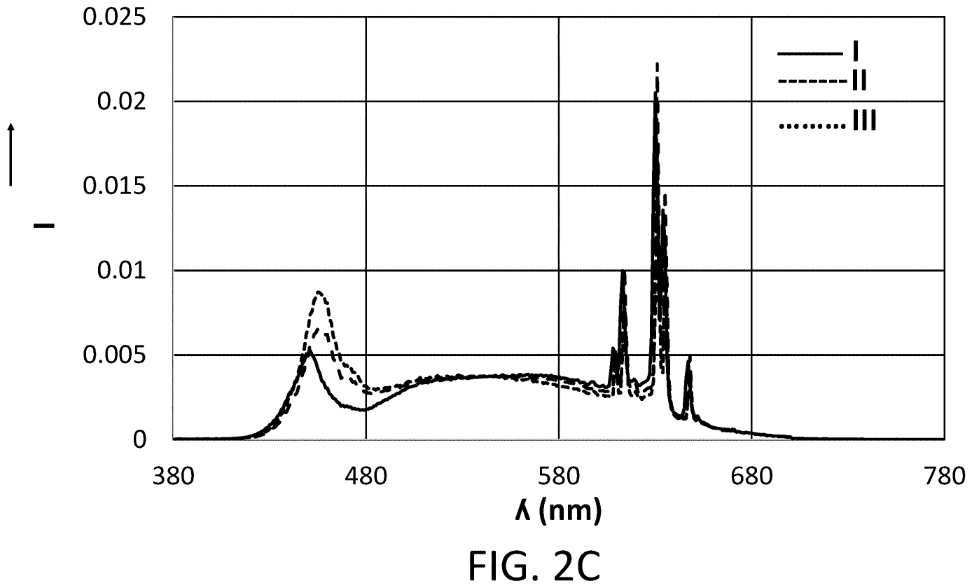

FIGS. 2a-2c show some spectral power distributions of the system light 1001.

Referring to FIG. 2a, embodiments I and II refer to spectral power distributions also comprising the second luminescent material light 221 with 13.3% and 16.9%, respectively, of the third luminescent material light 231 in the spectral power distribution of the light in the visible wavelength range. The CCTs are 3998 K and 4035 K, respectively, and the CRIs are 95.2 and 96.4, respectively. In embodiments I and II of FIG. 2a, the PWL of the light generating device 100 is 450 nm. In embodiments I and II, the first luminescent material is Y₃(Al,Ga)₅O₁₂:Ce³⁺ with a color point (u′,v′) of (0.160, 0.557). In embodiment I, the second luminescent material is (Ca, Sr)AlSiN₃:Eu²⁺ with a color point (u′,v′) of (0.412, 0.538). In embodiment II, the second luminescent material is (Ca, Sr)AlSiN₃:Eu²⁺ with a color point (u′,v′) of (0.338, 0.549). In embodiments I and II, the third luminescent material is K₂SiF₆:Mn⁴⁺ with a color point (u′,v′) of (0.531, 0.520). The conversion efficiency is high, however, it is higher for embodiment II (higher Mn⁴⁺ luminescence contribution) than for embodiment I (lower Mn⁴⁺ luminescence contribution).

Details on the peak wavelength of the light generating device, contributions of the luminescent materials to the total spectral power distribution of the system light 1001, and properties of the system light 1001 of the spectra shown in FIG. 2a are shown in Table 3, wherein “EB” refers to embodiment, “LGD (%)” refers to the contribution of the non-converted light from the light generating device to the total spectral power distribution of the system light, “FLM (%)” refers to the contribution of the first luminescent material light to the total spectral power distribution of the system light, “SLM (%)” refers to the contribution of the second luminescent material light to the total spectral power distribution of the system light, “TLM (%)” refers to the contribution of the third luminescent material light to the total spectral power distribution of the system light, “CRI’ refers to the color rendering index, “CCT” refers to the correlated color temperature and “LER” refers to the luminous efficacy.

TABLE 3

| | PWL | LGD | FLM | SLM | TLM | | | | | | | LER |
|---|---|---|---|---|---|---|---|---|---|---|---|---|
| EB | (nm) | (%) | (%) | (%) | (%) | Rf | Rf, h1 | Rg | Rcs, h1 | CCT (K) | CRI | (lm W⁻¹) |
| I | 450 | 19.0 | 52.8 | 14.9 | 13.3 | 93.6 | 95.2 | 103.9 | 0.1 | 3998 | 95.2 | 315 |
| II | 450 | 19.0 | 52.7 | 11.4 | 16.9 | 93.7 | 95.1 | 102.8 | −0.6 | 4035 | 96.4 | 328 |

Referring to FIG. 2b, embodiments I, II, and III refer to spectral power distributions without the second luminescent material light 221 with CCTs of 4000 K, 5000 K, and 6500 K, respectively. The higher the CCT, the relatively higher the blue peak intensity. In embodiments I, II and III of FIG. 2b, the PWL of the light generating device 100 is 455 nm, 455 nm, and 450 nm, respectively. In embodiment I, the first luminescent material is Y₃Al₅O₁₂:Ce³⁺ with a color point (u′,v′) of (0.191, 0.565). In embodiment II, the first luminescent material is Y₃(Al,Ga)₅O₁₂:Ce³⁺ with a color point (u′,v′) of (0.179, 0.563). In embodiment III, the first luminescent material is Y₃(Al,Ga)₅O₁₂:Ce³⁺ with a color point (u′,v′) of (0.160, 0.557). In embodiments I, II and III, the third luminescent material is K₂SiF₆:Mn⁴⁺ with a color point (u′,v′) of (0.531, 0.520). The contribution of the third luminescent material light 231 in the spectral power distribution of the light in the visible wavelength range is 17.7, 14.0, and 14.4, respectively. The conversion efficiency is also high, and decreases with increasing CCT.

Details on the peak wavelength of the light generating device, contributions of the luminescent materials to the total spectral power distribution of the system light, and properties of the system light of the spectra shown in FIG. 2b are shown in Table 4, wherein “EB” refers to embodiment, “LGD (%)” refers to the contribution of the non-converted light from the light generating device to the total spectral power distribution of the system light, “FLM (%)” refers to the contribution of the first luminescent material light to the total spectral power distribution of the system light, “TLM (%)” refers to the contribution of the third luminescent material light to the total spectral power distribution of the system light, “CRI’ refers to the color rendering index, “CCT” refers to the correlated color temperature and “LER” refers to the luminous efficacy.

TABLE 4

| | PWL | LGD | FLM | TLM | | | | | | | LER |
|---|---|---|---|---|---|---|---|---|---|---|---|
| EB | (nm) | (%) | (%) | (%) | Rf | Rf, h1 | Rg | Rcs, h1 | CCT (K) | CRI | (lm W⁻¹) |
| I | 455 | 21.2 | 61.1 | 17.7 | 91.2 | 94.1 | 102.2 | −0.7 | 4000 | 95.1 | 331 |
| II | 455 | 26.2 | 59.8 | 14.0 | 91.8 | 92.9 | 102.2 | 0.5 | 5000 | 95.3 | 314 |
| III | 450 | 29.2 | 56.4 | 14.4 | 91.9 | 91.0 | 104.8 | 3.1 | 6500 | 92.2 | 299 |

Referring to FIG. 2c, embodiments I, II, and III refer to spectral power distributions of the system light 1001 with the second luminescent material light 221 with CCTs of 4035 K, 5003 K, and 6495 K, respectively. The higher the CCT, the relatively higher the blue peak intensity. In embodiments I, II and III of FIG. 2c, the PWL is 450 nm, 455 nm, and 455 nm, respectively. In embodiments I, II and III, the first luminescent material is Y₃(Al,Ga)₅O₁₂:Ce³⁺ with a color point (u′,v′) of (0.160, 0.557). In embodiments I and II, the second luminescent material is (Ca, Sr)AlSiN₃:Eu²⁺ with a color point (u′,v′) of (0.338, 0.549). In embodiment III, the second luminescent material is (Ca, Sr)AlSiN₃:Eu²⁺ with a color point (u′,v′) of (0.376, 0.543). In embodiments I, II and III, the third luminescent material is K₂SiF₆:Mn⁴⁺ with a color point (u′,v′) of (0.531, 0.520). The contribution of the third luminescent material light 231 in the spectral power distribution of the light in the visible wavelength range is 18.0%, 15.1%, and 11.5%, respectively. The conversion efficiency is also high and decreases with increasing CCT.

Details on the peak wavelength of the light generating device, contributions of the luminescent materials to the total spectral power distribution of the system light 1001, and properties of the system light of the spectra shown in FIG. 2c are shown in Table 5, wherein “EB” refers to embodiment, “LGD (%)” refers to the contribution of the non-converted light from the light generating device to the total spectral power distribution of the system light, “FLM (%)” refers to the contribution of the first luminescent material light to the total spectral power distribution of the system light, “SLM (%)” refers to the contribution of the second luminescent material light to the total spectral power distribution of the system light, “TLM (%)” refers to the contribution of the third luminescent material light to the total spectral power distribution of the system light, “CRI’ refers to the color rendering index, “CCT” refers to the correlated color temperature and “LER” refers to the luminous efficacy.

TABLE 5

| | PWL | LGD | FLM | SLM | TLM | | | | | CCT | | LER |
|---|---|---|---|---|---|---|---|---|---|---|---|---|
| EB | (nm) | (%) | (%) | (%) | (%) | Rf | Rf, h1 | Rg | Rcs, h1 | (K) | CRI | (lm W⁻¹) |
| I | 450 | 19.0 | 52.7 | 10.3 | 18.0 | 94 | 95.1 | 103 | −0.6 | 4035 | 96.4 | 328 |
| II | 455 | 25.0 | 52.2 | 7.7 | 15.1 | 91 | 92.4 | 100 | −0.4 | 5003 | 95.6 | 313 |
| III | 455 | 30.5 | 52.6 | 5.4 | 11.5 | 90 | 90.1 | 99 | 0.2 | 6495 | 94.7 | 297 |

Further embodiments of a light generating device according to the invention for generating system light 1001 with the second luminescent material light 221 are shown in Table 6. In embodiments A and B, the first luminescent material is Y₃(Al, Ga)₅O₁₂:Ce³⁺ with a color point (u′,v′) of (0.160, 0.557). In embodiments A and N, the second luminescent material is (Ca, Sr)AlSiN₃:Eu²⁺ with a color point (u′,v′) of (0.338, 0.549). In embodiments A and B, the third luminescent material is K₂SiF₆:Mn⁴⁺ with a color point (u′,v′) of (0.531, 0.520). Details on the peak wavelength of the light generating device, contributions of the luminescent materials to the total spectral power distribution of the system light, and properties of the system light are shown in Table 6, wherein “EB” refers to embodiment, “LGD (%)” refers to the contribution of the non-converted light from the light generating device to the total spectral power distribution of the system light, “FLM (%)” refers to the contribution of the first luminescent material light to the total spectral power distribution of the system light, “SLM (%)” refers to the contribution of the second luminescent material light to the total spectral power distribution of the system light, “TLM (%)” refers to the contribution of the third luminescent material light to the total spectral power distribution of the system light, “CRI’ refers to the color rendering index, “CCT” refers to the correlated color temperature and “LER” refers to the luminous efficacy.

TABLE 6

| | PWL | LGD | FLM | SLM | TLM | | | | | CCT | | LER |
|---|---|---|---|---|---|---|---|---|---|---|---|---|
| EB | (nm) | (%) | (%) | (%) | (%) | Rf | Rf, h1 | Rg | Rcs, h1 | (K) | CRI | (lm W⁻¹) |
| A | 450 | 17.9 | 53.3 | 10.7 | 18.1 | 93 | 95.0 | 102.1 | −0.6 | 3999 | 96.8 | 330 |
| B | 455 | 19.3 | 52.7 | 9.8 | 18.2 | 93 | 94.9 | 103.3 | −0.1 | 4141 | 95.7 | 325 |

Especially, the system may be configured such that the system light 1001 is white light having a correlated color temperature CCT selected from the range of 1800-6500 K, an R_{f} value of at least 85, an R_{f,h1} value of at least 85, an R_{g} value of at least 95, and an R_{cs,h1} value of at least −1%, wherein R_{f}, R_{f,h1}, R_{g}, and R_{cs,h1} are defined according to TM-302020 standard ANSI/IES TM-30-20: IES Method for Evaluating Light Source Color Rendition, wherein a contribution to a spectral power distribution of the system light 1001 in the wavelength range of 380-780 nm by the third luminescent material light 231 is defined as a fraction G, and wherein the following applies: (a) when the system light 1001 (also) comprises the second luminescent material light 221, the fraction G is selected from the range of 0.95*G′-1.05*G′, wherein G′ complies with the following formula: G′=1.4421−2.904125*10⁻⁸*PWL−10.08921*u′_{Yellow}−0.5457286*u′_{Red}−1.074782*10⁻⁴*CCT+21.623*[u′_{Yellow}]²−1.639*[u′_{Red}]²+4.921703*10⁻⁹*[CCT]²+2.316461*10⁻⁷*[PWL*u′_{Red}]+7.268292*[u′_{Yellow}*u′_{Red}]+9.309924*10⁻⁵*[u′_{Red}*CCT], and wherein the fraction G is at least 0.05 and at maximum 0.2; or (b) when the system light 1001 does not comprise the second luminescent material light 221 the following applies: u′_{Yellow} 0.95*0.2546−0.000016*CCT, and the fraction G is at least 0.05 and at maximum 0.2. The spectral power distributions displayed herein all comply with these conditions. Further, the CRIs are all above 89, or even above 91. For instance, R_{f} values were over 86, R_{g} values were all above 96, R_{f,h1} values were all above 88, and R_{cs,h1} values are all above-0.6%.

Especially, G may be selected from the range of 0.97*G′-1.03*G′ or wherein u′_{Yellow}≥0.97*0.2546−0.000016*CCT; more especially, G may be selected from the range of 0.99*G′-1.01*G′ or wherein u′_{Yellow}≥0.99*0.2546−0.000016*CCT. Especially, in embodiments the fraction G is at least 0.1.

In embodiments, wherein the system light 1001 does not comprise the second luminescent material light 221, the correlated color temperature may be selected from the range of at least 3800 K, such as selected from the range of 4000-6500 K. Especially, in such embodiments the correlated color temperature is at least 3800 K and A in A₃B₅O₁₂:Ce³⁺ comprises Gd and/or wherein B in A₃B₅O₁₂:Ce³⁺ comprises less than 10% Ga. As indicated above, in specific embodiments (see also FIG. 1a), the two or more luminescent materials 200 consist of the first luminescent material 210 and the third luminescent material 230. Especially, in such embodiments the first luminescent material light 211 may have a color point selected from the ranges of 0.15≤u′≤0.200 and 0.555≤v′≤0.575.

However, in other embodiments, see also FIG. 1a, the system light 1001 comprises the second luminescent material light 221. In specific embodiments, the two or more luminescent materials 200 may consist of the first luminescent material 210, the second luminescent material 220, and the third luminescent material 230.

In embodiments, the spectral power distribution of the system light 1001 may have the contributions as defined in the table 1 (above). For instance, this may apply to the spectral power distributions shown in FIG. 2a-2b.

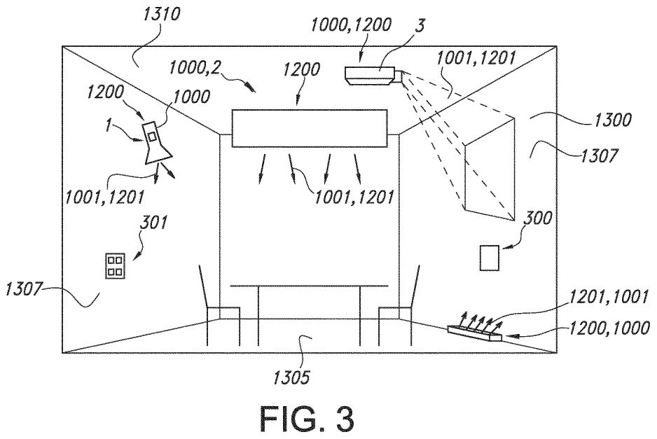

FIG. 3 schematically depicts an embodiment of a luminaire 2 comprising the light generating system 1000 as described above. Reference 301 indicates a user interface which may be functionally coupled with the control system 300 comprised by or functionally coupled to the light generating system 1000. FIG. 3 also schematically depicts an embodiment of lamp 1 comprising the light generating system 1000. Reference 3 indicates a projector device or projector system, which may be used to project images, such as at a wall, which may also comprise the light generating system 1000. Hence, FIG. 3 schematically depicts embodiments of a lighting device 1200 selected from the group of a lamp 1, a luminaire 2, a projector device 3, a disinfection device, a photochemical reactor, and an optical wireless communication device, comprising the light generating system 1000 as described herein. In embodiments, such lighting device may be a lamp 1, a luminaire 2, a projector device 3, a disinfection device, or an optical wireless communication device. Lighting device light escaping from the lighting device 1200 is indicated with reference 1201. Lighting device light 1201 may essentially consist of system light 1001, and may in specific embodiments thus be system light 1001. Reference 1300 refers to a space, such as a room. Reference 1305 refers to a floor and reference 1310 to a ceiling; reference 1307 refers to a wall.

The term “plurality” refers to two or more.

The terms “substantially” or “essentially” herein, and similar terms, will be understood by the person skilled in the art. The terms “substantially” or “essentially” may also include embodiments with “entirely”, “completely”, “all”, etc. Hence, in embodiments the adjective substantially or essentially may also be removed. Where applicable, the term “substantially” or the term “essentially” may also relate to 90% or higher, such as 95% or higher, especially 99% or higher, even more especially 99.5% or higher, including 100%.

The term “comprise” also includes embodiments wherein the term “comprises” means “consists of”.

The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices, apparatus, or systems may herein amongst others be described during operation. As will be clear to the person skilled in the art, the invention is not limited to methods of operation, or devices, apparatus, or systems in operation.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

Use of the verb “to comprise” and its conjugations does not exclude the presence of elements or steps other than those stated in a claim. Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

The article “a” or “an” preceding an element does not exclude the presence of a plurality of such elements.

The invention may be implemented by means of hardware comprising several distinct elements, and by means of a suitably programmed computer. In a device claim, or an apparatus claim, or a system claim, enumerating several means, several of these means may be embodied by one and the same item of hardware. The mere fact that certain measures are recited in mutually different dependent claims does not indicate that a combination of these measures cannot be used to advantage. In yet a further aspect, the invention (thus) provides a software product, which, when running on a computer is capable of bringing about (one or more embodiments of) the method as described herein.

The invention also provides a control system that may control the device, apparatus, or system, or that may execute the herein described method or process. Yet further, the invention also provides a computer program product, when running on a computer which is functionally coupled to or comprised by the device, apparatus, or system, controls one or more controllable elements of such device, apparatus, or system.

The invention further applies to a device, apparatus, or system comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

1. A light generating system comprising a light generating device and two or more luminescent materials, wherein:
the light generating device is configured to generate device light having a peak wavelength, PWL, selected from the wavelength range of 440-465 nm; wherein the light generating device comprises a solid state light source;
the two or more luminescent materials comprise (i) a first luminescent material configured to convert at least part of the device light into first luminescent material light having spectral power within the green-yellow wavelength range, a full width half maximum of at least 50 nm, and a color point u′_{yellow}, v′_{yellow}, wherein the first luminescent material comprises a luminescent material of the type A₃B₅O₁₂:Ce³⁺, wherein A comprises one or more of Y, La, Gd, Tb and Lu, and wherein B comprises one or more of Al, Ga, In and Sc; (ii) optionally a second luminescent material configured to convert at least part of the device light into second luminescent material light having spectral power within the orange-red wavelength range, a full width half maximum of at least 50 nm, and a color point u′_{red}, v′_{red}, wherein the second luminescent material comprises one or more luminescent materials of the type MS:Eu²⁺, M₂Si₅N₈:Eu²⁺, MAlSiN₃:Eu²⁺ and Ca₂AlSi₃O₂N₅:Eu²⁺, wherein M comprises one or more of Ba, Sr and Ca; and (iii) a third luminescent material configured to convert at least part of the device light into third luminescent material light within the orange-red wavelength range, wherein the third luminescent material comprises M′ₓM₂₋₂ₓAX₆ doped with tetravalent manganese, wherein M′ comprises an alkaline earth cation, wherein M comprises a cation, and x is in the range of 0-1, wherein A comprises a tetravalent cation, wherein X comprises a monovalent anion, at least comprising fluorine;
the first luminescent material having a color point selected from the ranges of 0.135≤u′≤0.200 and 0.555≤v′≤0.575; the second luminescent material having a color point selected from the ranges of 0.33≤u′≤0.48 and 0.525≤v′≤0.555; and the third luminescent material having a color point selected from the ranges of 0.52≤u′≤0.54 and 0.51≤v′≤0.53;
the light generating system is configured to generate system light comprising (i) at least part of the device light (101), (ii) at least part of the first luminescent material light, and (iii) at least part of the third luminescent material light; wherein the system is configured such that the system light is white light having a correlated color temperature (CCT) selected from the range of 1800-6500 K, an R_{f} value of at least 85, an R_{f,h1} value of at least 85, an R_{g} value of at least 95, and an R_{cs,h1} value of at least −1%, wherein R_{f}, R_{f,h1}, R_{g}, and R_{cs,h1} are defined according to TM-30 (2020) standard ANSI/IES TM-30-20: IES Method for Evaluating Light Source Color Rendition, wherein a contribution to a spectral power distribution of the system light in the wavelength range of 380-780 nm by the third luminescent material light is defined as a fraction G, and wherein the following applies:
(a) when the system light comprises the second luminescent material light, the fraction G is selected from the range of 0.95*G′-1.05*G′, wherein G′ complies with the following formula:
$${G}^{′} = 1.4421 - 2.904125 * {10}^{- 8} * PWL - 10.08921 * {u}_{Yellow}^{′} - 0.5457286 * {u}_{R e d}^{′} - 1.074782 * {10}^{- 4} * CCT + 21.623 * {[ {u}_{Yellow}^{′} ]}^{2} - 1.639 * {[ {u}_{R e d}^{′} ]}^{2} + 4.9 \; 21703 * {10}^{- 9} * {[ CCT ]}^{2} + 2.3 \; 16461 * {10}^{- 7} * [ PWL * {u}_{R e d}^{′} ] + 7.268292 * [ {u}_{Yellow}^{′} * {u}_{R e d}^{′} ] + 9.3 \; 09924 * {10}^{- 5} * [ {u}_{Red}^{′} * CCT ]$$
and wherein the fraction G is at least 0.05 and at maximum 0.2; or
(b) when the system light does not comprise the second luminescent material light, the following applies: u′_{Yellow}≥0.95*(0.2546−0.000016*CCT), and the fraction G is at least 0.05 and at maximum 0.2.

2. The light generating system according to claim 1, wherein G is selected from the range of 0.97*G′-1.03*G′ or wherein u′_{Yellow}≥0.97*(0.2546−0.000016*CCT);
and wherein the correlated color temperature (CCT) is selected from the range of 2700-6500 K.

3. The light generating system according to claim 1, wherein the first luminescent material comprises one or more of Lu₃Al₅O₁₂:Ce³⁺, Y₃Al₅O₁₂:Ce³⁺, Y₃(Al,Ga)₅O₁₂:Ce³⁺, and (Gd, Y)₃Al₅O₁₂:Ce³⁺.

4. The light generating system according to claim 1, wherein for M′ₓM₂₋₂ₓAX₆ doped applies that x=0 and M comprises one or more of K and Rb, wherein A comprises Si, and wherein X═F; and wherein G is selected from the range of 0.99*G′-1.01*G′ or wherein u′_{Yellow}≥0.99*(0.2546−0.000016*CCT); and wherein the correlated color temperature (CCT) is selected from the range of 2700-6500 K.

5. The light generating system according to claim 1, wherein the device light has a peak wavelength selected from the wavelength range of 445-460 nm.

6. The light generating system according to claim 1, wherein the fraction G is at least 0.1.

7. The light generating system according to claim 1, wherein the system light does not comprise the second luminescent material light, and wherein the correlated color temperature is selected from the range of 4000-6500 K.

8. The light generating system according to claim 7, wherein the two or more luminescent materials consist of the first luminescent material and the third luminescent material.

9. The light generating system according to claim 1, wherein the system light comprises the second luminescent material light; wherein the second luminescent material comprises one or more of the luminescent materials selected from the group consisting of (Sr,Ca)S:Eu²⁺, (Sr,Ca)AlSiN₃:Eu²⁺ and (Sr,Ca)₂Si₅N₈:Eu²⁺.

10. The light generating system according to claim 9, wherein the two or more luminescent materials consist of the first luminescent material, the second luminescent material, and the third luminescent material.

11. The light generating system according to claim 1, wherein (i) the first luminescent material is of the type A₃B₅O₁₂:Ce³⁺, wherein A comprises one or more of Y and Lu, and wherein B comprises one or more of Al and Ga, (ii) wherein the second luminescent material (220) is of the type MAlSiN₃:Eu²⁺, wherein M comprises one or more of Sr and Ca and (iii) wherein the third luminescent material is of the type M₂AX₆ doped with tetravalent manganese, wherein M comprises one or more of Na, K and Rb, wherein A comprises one or more of Si, Ti and Ge, and wherein X is fluorine.

12. The light generating system according to claim 7, wherein the first luminescent material light has a color point selected from the ranges of 0.15≤u′≤0.200 and 0.555≤v′≤0.575.

13. The light generating system according to claim 1, wherein the spectral power distribution of the system light has the following contributions:

| Wavelength range | min | max |
|---|---|---|
| 380-400 nm | 0% | 1% |
| 400-420 nm | 0% | 1% |
| 420-440 nm | 0% | 3% |
| 440-460 nm | 6% | 11% |
| 460-480 nm | 1% | 9% |
| 480-500 nm | 2% | 9% |
| 500-520 nm | 6% | 9% |
| 520-540 nm | 7% | 10% |
| 540-560 nm | 7% | 11% |
| 560-580 nm | 7% | 10% |
| 580-600 nm | 7% | 10% |
| 600-620 nm | 9% | 12% |
| 620-640 nm | 12% | 19% |
| 640-660 nm | 3% | 6% |
| 660-680 nm | 1% | 3% |
| 680-700 nm | 0% | 2% |
| 700-720 nm | 0% | 1% |
| 720-740 nm | 0% | 1% |
| 740-760 nm | 0% | 1% |
| 760-780 nm | 0% | 1% |

14. The light generating system according to claim 1, wherein the light generating system comprises a chip-on-board, a LED filament, or a LED package, comprising the light generating device and the two or more luminescent materials.

15. A lighting device selected from the group of a lamp (1), a luminaire (2), a projector device (3), a disinfection device, a photochemical reactor, and an optical wireless communication device, comprising the light generating system according to claim 1.
